(19) United States
(12) Patent Application Publication
(10) Pub. No.: US 2026/0244298 A1
(43) Pub. Date: Aug. 20, 2026

(54) PACKAGED LIGHT EMITTING DIODE AND TOUCH SENSITIVE APPARATUS HAVING THE SAME

(71) Applicant: UNIPHY LIMITED, Leeds (GB)

(72) Inventors: David LOMAS, Leeds (GB); Mike BEAN, Leeds (GB)

(21) Appl. No.: 19/472,009

(22) PCT Filed: Apr. 3, 2024
(86) PCT No.: PCT/EP2024/059109

§ 371 Date: Oct. 7, 2025

(30) Foreign Application Priority Data
Apr. 3, 2023 (GB) 2304947.1

(51) Int. Cl. G06F 3/042; H10H 20/853; H10H 20/856

(52) U.S. Cl. CPC G06F 3/0421; H10H 20/853; H10H 20/856; G06F 2203/04109

(57) ABSTRACT

A packaged light emitting diode comprises a light emitting diode die and a cylindrical lens. The cylindrical lens is provided directly over a light emitting surface of the light emitting diode die. The cylindrical lens is advantageously provided as a truncated substantially oblate ellipsoidal lens in a body having two first truncations and one second truncation. As an alternative, the cylindrical lens is provided as an aspherical lens in a modified ellipsoidal body having again two first truncations and one second truncation. Light emitted through the lens has a narrow angular distribution along a first axis and a broad angular distribution along a second axis, orthogonal to the first axis. A touch sensitive apparatus comprising one or more such packaged light emitting diodes, being integrated within a top light-guiding plate of said apparatus, is also described.

### TECHNICAL FIELD

The present disclosure relates to a light emitting diode and to an optical system, particularly one suitable for use in a touch-sensitive device. Embodiments of the touch-sensitive device are particularly suitable for use in a controller for an electronic, human display interface (HDI), such as an automotive central console, a laundry machine panel, a handheld gaming controller, or other suitable smart controller HDI.

### BACKGROUND

Currently, in a typical optical touch sensitive screen, light is injected from light emitting diode (LED) emitters through the peripheral edges of the plate which may be convenient to implement, but can result in inefficient optical illumination of the specific touch sensitive areas. This is typically caused by either the light diminishing in power as it traverses long distances through the lightguide, or light not being directed to where it is most needed. This optical inefficiency results in more LED emitters being used than might be necessary and a higher electrical power consumption which is detrimental in systems where electrical power management is critical. Such drawbacks may be found in other arrangements that use a generally planar lightguide.

It is an aim of the present invention to address one or more of the disadvantages associated with the prior art.

### SUMMARY OF THE INVENTION

In a first aspect, the invention provides a packaged light emitting diode comprising a light emitting diode die, and a cylindrical lens mounted directly over a light emitting surface of the light emitting diode die, whereby light emitted through the cylindrical lens has a narrow angular distribution along a first axis and a broad angular distribution along a second axis orthogonal to the first axis.

Using this approach, a light emitting diode can be provided that lacks the deficiencies of existing LEDs, which while varying in angle generally have similar distributions in orthogonal directions. Neither approach is suitable for providing effective coupling of light from an LED into a plate to allow light to travel with total internal reflection in that plate, particularly with a broadly even distribution. This can be achieved if the lens shape comprises a section of a superellipse or hyperellipse-such lenses are referred to below as hyperelliptical lenses.

In one type of embodiment, the cylindrical lens is formed as a truncated substantially oblate ellipsoidal lens in a body having two first truncations and one second truncation, wherein the two first truncations are normal to the axis of the oblate ellipsoid and equidistant from a longest semidiameter of the oblate ellipsoid, and are parallel to two axes of the oblate ellipsoid and to each other, and wherein the second truncation is parallel to the other axis of the oblate ellipsoid and normal to the two first truncations; and wherein the light emitting diode die is proximate to the second truncation. Here, the lens may be an oblate spheroid.

In another type of embodiment, the cylindrical lens is formed as an aspherical lens in a modified ellipsoidal body, the modified ellipsoidal body having two first truncations and one second truncation, wherein the two first truncations are normal to the axis of the modified ellipsoid and equidistant from a longest semidiameter of the modified ellipsoid, and are parallel to two axes of the oblate ellipsoid and to each other, and wherein the second truncation is parallel to the other axis of the oblate ellipsoid and normal to the two first truncations; and wherein the light emitting diode die is proximate to the second truncation, and wherein the ellipsoid is modified to have greater curvature than an ellipsoid in a direction normal to the light emitting surface of the light emitting diode die and to have lesser curvature than an ellipsoid in a direction parallel to the light emitting surface of the light emitting diode die.

In either type of embodiment, a length of the two first truncations normal to the light emitting surface of the light emitting diode die may be more than half a length of the lens body normal to the light emitting surface of the light emitting diode die. The light emitting diode may be a near infrared light emitting diode.

In a second aspect, the invention provides a touch sensitive apparatus, comprising: a top plate having one or more light sources associated therewith, such that light from the one or more light sources is transmitted within the top plate with total internal reflection; and a base plate having one or more detectors associated therewith for detecting light transmitted within the base plate; wherein the top plate and the base plate are configured such that if an external body touches a first surface of the top plate, then light is coupled from a second surface of the top plate into the base plate through a first surface of the base plate; wherein each of the one or more light sources is disposed within the top plate such that light from a light source is coupled into the body of the top plate through an input face of the top plate, and wherein each of the one or more light sources is a packaged light emitting diode as described with respect to the first aspect.

Using this approach, light can be coupled particularly effectively into the top plate to achieve a uniform distribution of light oriented for total internal reflection within the top plate without the introduction of stray light that is not so oriented. This preponderance of “useful” light within the top plate is effective to reduce noise and thus increase signal-to-noise for the device.

In embodiments, each light source may be disposed within a recess, and wherein the input face is a face of the recess. The mounting of each of the one or more light sources with respect to the input face may be such that a combination of the lens of the light source and shaping of the input face is adapted to spread light substantially evenly in the plane of the top plate. In different embodiments, in the combination of the light source and the input face, the input face may have no optical power, or may have a lensing effect.

The wall of the or each refracting input face may form an angle to the plane of the top plate such that the refracting input face and the second surface of the top plate form an obtuse angle within the top plate. Each of the light sources may be mounted at an angle to a plane of the top plate such that light emitted from the or each light source is predominantly directed obliquely towards the first surface. In such cases, each of the light sources may be mounted such that light emitted from the light source is directed obliquely towards the refracting input face.

In addition to the primary aspects of the present invention as set out above, embodiments of the invention also demonstrate the following secondary aspects. The primary aspects of the invention as set out above may be combined with the following secondary aspects, or individual features of the following secondary aspects, to provide further aspects of the invention.

In a first such aspect, there is provided a touch sensitive apparatus, comprising: a top plate having a plurality of light sources associated therewith, such that light from the plurality of light sources is transmitted within the top plate with total internal reflection; and a base plate having one or more detectors associated therewith for detecting light transmitted within the base plate. The top plate and the base plate are configured such that if an external body touches a first surface of the top plate, then light is coupled from a second surface of the top plate into the base plate through a first surface of the base plate. The plurality of light sources are disposed within a linearly extending recess in the second surface of the top plate such that light from the plurality of light sources is coupled into the top plate through a wall of the recess. The plurality of light sources form a linear array within said linearly extending recess.

Having a recess that extends linearly along the second surface of the top plate-in effect, forming a trench in the second surface-allows the light sources to be mounted so that light can easily be injected directly into the body of the top plate. This allows light to be injected evenly, and with great efficiency, into the top plate.

The linearly extending recess may extend as a straight line, or it may be curved. Similarly, the linear array of light sources may be in a straight or a curved line.

The wall of the recess may form an angle to the plane of the top plate such that the wall and the second surface of the top plate form an obtuse angle within the top plate.

The mounting of the light source relative to the wall of the or each refracting face may be such as to refract light thereby increasing evanescent field strength while containing light within the top plate through total internal reflection.

The wall of the recess may be lensed.

Each of the light sources may be mounted at an angle to a plane of the top plate such that light emitted from the light source is predominantly directed obliquely towards the first surface.

Each of the plurality of light sources may be mounted such that light emitted from the light source is predominantly directed obliquely towards the wall of the recess.

Angling the mounting of the light source relative to the wall of the recess in this way can be used to increase or otherwise tailor the evanescent field strength, thereby maximising or adjusting the responsiveness of the apparatus to touch.

The top plate may further comprise a reduced width section in which the distance between the first surface and the second surface is substantially constant, but is less than the distance between the first surface and the second surface at the recess.

While some such embodiments have a top plate of substantially uniform thickness, excluding the recess, other arrangements are possible and can provide enhanced possibilities for control of the totally internally reflected light.

The top plate may further comprise a tapered section in which the distance between the first surface and the second surface of the top plate is reduced, the tapered section lying between the recess and the reduced width section.

The tapered section may taper linearly. The tapered section may taper non-linearly.

A region of the first surface may be masked to prevent total internal reflection of light from the plurality of light sources in the trench.

Masking may be provided for a section of the first surface lying over the recess and extending beyond the recess to limit an angular range of light incident for reflection at the first surface from the plurality of light sources.

The masking may be provided by a light absorbing layer provided on or at the first surface.

A region of the recess between the light sources and the first surface may be masked.

The masking may be provided by a light absorbing layer provided on or at a surface of the recess.

The masking may be provided by a light absorbing element mounted with the light sources.

The masking of the region of the recess defines an aperture for emission of light from the light sources into the top plate.

The top plate may have a linear protrusion on the second surface extending away from the first surface, wherein a linear extension of the linear protrusion is substantially parallel to the linear extension of the trench. The linear protrusion may have a rectangular or scalloped cross-section normal to its linear extent.

In some embodiments there may be an air gap between the top plate and the bottom plate. In other embodiments there may be an optically transmitting material layer between the top plate and the bottom plate.

The plurality of light sources may be spaced to form a substantially uniform light distribution in a body of the top plate. Each of the plurality of light sources may be a light emitting diode. Each light emitting diode may emit light in the near infrared.

In another such aspect, there is provided a touch sensitive apparatus, comprising: a top plate having one or more light sources associated therewith, such that light from the one or more light sources is transmitted within the top plate with total internal reflection; and a base plate having one or more detectors associated therewith for detecting light transmitted within the base plate. The top plate and the base plate are configured such that if an external body touches a first surface of the top plate, then light is coupled from a second surface of the top plate into the base plate through a first surface of the base plate. Each of the one or more light sources is disposed within the top plate in a recess for that light source, wherein the recess has one or more refracting input faces such that light from a light source is coupled into the body of the top plate through the one or more refracting input faces.

For one or more of the light sources, the recess may have a central refracting input face and two side refracting faces disposed symmetrically about and adjacent to the central refracting input face.

The central refracting input face may have different curvature from the side refracting faces. In some embodiments the central refracting input face may have conical curvature. In some embodiments the central refracting input face may have elliptical curvature.

The wall of the or each refracting input face may form an angle to the plane of the top plate such that the refracting input face and the second surface of the top plate form an obtuse angle within the top plate.

The mounting of the light source relative to the wall of the or each refracting face may be such as to refract light thereby increasing evanescent field strength while containing light within the top plate through total internal reflection.

The wall of the or each refracting input face may be lensed.

The or each of the light sources may be mounted at an angle to a plane of the top plate such that light emitted from the light source is predominantly directed obliquely towards the first surface.

Each of the light sources may be mounted such that light emitted from the light source is predominantly directed obliquely towards at least one refracting input face.

Angling the mounting of the light source relative to the wall of the recess in this way can be used to increase or otherwise tailor the evanescent field strength, thereby maximising or adjusting the responsiveness of the apparatus to touch.

The top plate may further comprise a reduced width section in which the distance between the first surface and the second surface is substantially constant, but is less than the distance between the first surface and the second surface at the recess. The top plate may further comprise a tapered section in which the distance between the first surface and the second surface of the top plate is reduced, the tapered section lying between the recess and the reduced width section.

The tapered section may taper linearly. The tapered section may taper non-linearly.

In some embodiments there may be an air gap between the top plate and the bottom plate. In other embodiments there may be an optically transmitting material layer between the top plate and the bottom plate.

A region of the first surface may be masked to prevent total internal reflection of light from each light source in a recess. Masking may be provided for a section of the first surface lying over the recess and extending beyond the recess to limit an angular range of light incident for reflection at the first surface from the plurality of light sources. Masking may be provided by a light absorbing layer provided on or at the first surface.

The touch sensitive apparatus may comprise a plurality of light sources. The masking may extend over two or more of the plurality of light sources.

The masking may define an active area of the top plate, wherein the plurality of light sources illuminate the active area of the top plate.

The plurality of light sources may be disposed around a perimeter of the active area. The perimeter of the active area may be rectangular. The perimeter of the active area may be an ellipse.

The first surface of the top plate in the active area may not be planar.

The plurality of light sources may be spaced to form a substantially uniform light distribution in the active area of the top plate.

A region of each recess between the light source and the first surface may be masked. The masking may be provided by a light absorbing layer provided on or at a surface of that recess.

The masking may also be provided by a light absorbing element mounted with the light source.

The masking of the region of the recess may define an aperture for emission of light from the light source into the top plate.

Each of the one or more light sources may be a light emitting diode. Each of the one or more light emitting diodes may emit light in the near infrared

In another such aspect, there is provided a touch sensitive apparatus, comprising: a top plate having one or more light sources associated therewith, such that light from the plurality of light sources is transmitted within the top plate with total internal reflection; and a base plate having one or more detectors associated therewith for detecting light transmitted within the base plate. The top plate and the base plate are configured such that if an external body touches a first surface of the top plate, then light is coupled from a second surface of the top plate into the base plate through a first surface of the base plate. One or more regions of the first surface, the second surface, or both is provided with a layer inhibiting internal reflection at that region of the surface, thereby providing optical separation between one part of the top plate and another part of the top plate.

The layer may be an absorbing layer.

The top plate may be formed by moulding, and the layer may be formed by two-shot moulding or in-mould labelling.

The layer may separate at least one active area from other regions of the first surface, wherein each active area is isolated from any other optical activity in the top plate. An active area may provide a single touch sensitive device functionality.

The touch sensitive device functionality may comprise one of a dial, a slider, a button, a toggle, and a touch screen.

Each of the plurality of light sources is disposed within the top plate in a recess for that light source. The recess may have one or more refracting input faces such that light from a light source is coupled into the body of the top plate through the one or more refracting input faces.

The wall of the or each refracting input face may form an angle to the plane of the top plate such that the refracting input face and the second surface of the top plate form an obtuse angle within the top plate.

The wall of the or each refracting input face may be lensed.

Each of the light sources may be mounted at an angle to a plane of the top plate such that light emitted from the light source is predominantly directed obliquely towards the first surface.

Each of the light sources may be mounted such that light emitted from the light source is predominantly directed obliquely to at least one refracting input face.

The plurality of light sources may be disposed around a perimeter of the active area. The perimeter of the active area may be rectangular. The perimeter of the active area may be an ellipse.

The first surface of the top plate in the active area may not be planar.

The plurality of light sources may be spaced to form a substantially uniform light distribution in the active area of the top plate. There may be a plurality of active areas separated by the layer.

Two of the plurality of active areas may have different touch sensitive device functionalities. Two of the plurality of active areas may have different optical characteristics. Two of the plurality of active areas may have light sources with different properties. Two of the plurality of active areas may be associated with regions of the base plate with different optical properties.

The touch sensitive apparatus may further comprise an absorbing layer at some or all of a periphery of the top plate.

Each of the one or more light sources may be a light emitting diode.

In some embodiments, the light sources may emit in the near infrared and the absorbing layer may absorb in the near infrared. One or more regions of the first surface may be provided with an additional layer. The additional layer may absorb in the visible spectrum. The additional layer may at least partially overlay the absorbing layer.

In another such aspect, there is provided a method of manufacturing an optically transmissive sheet. The method comprises: moulding the optically transmissive sheet as a laminate, wherein the optically transmissive sheet is adapted for total internal reflection at first and second faces of the optically transmissive sheet; and forming one or more light absorbing layer regions on either the first face, the second face, or both of the optically transmissive sheet, wherein the one or more light absorbing layer regions are formed in the moulding process.

The light absorbing layer regions may be formed by in mould labelling.

The light absorbing layer regions may comprise first regions that absorb light in the near infra-red region. The light absorbing layer regions may comprise second regions that absorb light in the visible region.

In another such aspect, there is provided a method of manufacturing an optical element for a touch screen apparatus, the method comprising: forming an optically transmissive sheet by the method of any preceding paragraph; laminating the optically transmissive sheet with an intermediate optical layer and a further optically transmissive sheet, wherein the intermediate optical layer has a lower refractive index than the optically transmissive sheets.

The intermediate optical layer may provide an optical bond between the optically transmissive sheets. The intermediate optical layer may comprise fluorinated ethylene propylene.

The optical element may be formed by two-shot moulding.

In another such aspect, there is provided a method of manufacturing a touch screen apparatus, the method comprising: manufacturing an optically transmissive sheet of any of the preceding paragraphs as a top plate, and mounting the top plate in the touch screen apparatus with a plurality of light sources mounted in association such that light from the plurality of light sources is transmitted within the top plate with total internal reflection; and mounting a base plate relative to the top plate such that if an external body touches a first surface of the top plate, then light is coupled from a second surface of the top plate into the base plate through a first surface of the base plate, and mounting one or more detectors in association with the base plate for detecting light transmitted within the base plate.

The top plate and the base plate may be mounted with an air gap between them. In such embodiments, the air gap may be provided by a foam mask separator.

The optically transmissive sheet may be manufactured by forming the optically transmissive sheet by the method of any preceding paragraph; and laminating the optically transmissive sheet with an intermediate optical layer and a further optically transmissive sheet, wherein the intermediate optical layer has a lower refractive index than the optically transmissive sheets, and wherein the base plate is the further optically transmissive sheet.

The base plate may be mounted over a display configured to emit light from the touch screen apparatus through the top plate.

The light absorbing layers may absorb light emitted by the light sources, and may be adapted to mask the light sources. The masking of the light sources may substantially restrict propagation of light from the light sources through the top plate such that substantially only light directed for total internal reflection at the surfaces of the top plate can be propagated.

The light sources may emit and the light absorbing layer regions may absorb in the near infrared.

The base plate may be a weak absorber of light emitted from the plurality of light sources. The base plate may be chemically doped with a weakly absorbing material.

The top plate may extend beyond the base plate. The one or more light sources may be mounted in regions of the top plate that extend beyond the base plate.

The top plate may be manufactured to taper from a thicker region where the one or more light sources are mounted to a thinner region where the top plate is disposed over the base plate.

The one or more light sources may be mounted in one or more recesses in the second surface of the top plate and may be disposed to transmit light into the top plate through a wall of the recess in which that light source is located.

The recess may be a linearly extending recess, and a plurality of light sources may be mounted in the recess in a linear array.

In some embodiments the linearly extending recess and the linear array may extend along a straight line. In other embodiments the linearly extending recess and the linear array may extend along a curved line.

One or more recesses may be formed for each of the one or more light sources. Each recess may have one or more refracting input faces such that light from a light source is coupled into the body of the top plate through the one or more refracting input faces.

The base plate may be mounted to prevent light emerging from the base plate and not received in the one or more detectors from passing into the top plate.

The above approaches, features and aspects may be used on their own or in combination. Features of one aspect may be applied, alone or in appropriate combination, to features of another aspect also.

### BRIEF DESCRIPTION OF THE DRAWINGS

In order that the invention may be more readily understood, preferred non-limiting embodiments thereof will now be described, by way of example only, with reference to the accompanying drawings, in which:

FIG. 1 is a schematic cross-sectional view of a touch screen arrangement;

FIG. 2 shows a touch screen arrangement incorporated in the cabin of a vehicle;

FIG. 3 is a cross-sectional view of a portion of a lightguide incorporating a light source disposed in a recess in the underside of the lightguide;

FIG. 4 is a cross-sectional view of a portion of another lightguide incorporating a light source disposed in a recess in the underside of the lightguide;

FIG. 5 is a perspective view of a portion of a lightguide incorporating a trench injection optic geometry and including a tapered section;

FIG. 6 is a perspective view of a portion of another lightguide incorporating a trench injection optic geometry and having a constant thickness;

FIG. 7 is a perspective view of a portion of a lightguide incorporating a pocket injection optic;

FIG. 8a illustrates the angular range of light rays that exceed the critical angle at a boundary between acrylic and air;

FIG. 8b illustrates the angular range of light rays that exceed the critical angle at a boundary between acrylic and FEP;

FIG. 9 is a cross-sectional view of a portion of a lightguide incorporating a light source disposed in a recess in the underside of the lightguide;

FIG. 10 is a cross-sectional view of a portion of another lightguide incorporating a light source disposed in a recess in the underside of the lightguide, where an absorbing mask is provided at the upper surface of the lightguide;

FIG. 11 is a perspective side view of a portion of a lightguide incorporating a recess for receiving a light source in use, where the recess has a lensed front wall;

FIG. 12a is a graph showing light lost from a lightguide in which light is injected into the lightguide from a light source disposed in a recess in the underside of the lightguide, as well as light coupled into the lightguide and power density in the lightguide, all for different angles of tilt of the front wall of the recess;

FIG. 12b is a cross-sectional view of a portion of a lightguide incorporating a light source disposed in a recess in the underside of the lightguide, where the front wall of the recess has no tilt;

FIG. 12c is a cross-sectional view of a portion of a lightguide incorporating a light source disposed in a recess in the underside of the lightguide, where the front wall of the recess has a tilt angle of 50°;

FIG. 13a is a graph showing light lost from a lightguide in which light is injected into the lightguide from a light source disposed in a recess in the underside of the lightguide, as well as light coupled into the lightguide and power density in the lightguide, all for different angles of tilt of the front wall of the recess;

FIG. 13b is a cross-sectional view of a portion of a lightguide incorporating a light source disposed in a recess in the underside of the lightguide, where the front wall of the light source cavity has no tilt and the light source has no tilt;

FIG. 13c is a cross-sectional view of a portion of a lightguide incorporating a light source disposed in a recess in the underside of the lightguide, where the front wall of the light source cavity has a tilt angle of 30°, and a central axis of the light source is approximately normal to the front wall of the recess;

FIG. 14 is a perspective side view of a portion of a lightguide incorporating a recess for receiving a light source in use, where the lightguide includes an extruded section or trench adjacent the front wall of the recess;

FIG. 15 is a perspective side view of a portion of another lightguide incorporating a recess for receiving a light source in use, where the lightguide includes a non-linear tapered section;

FIG. 16 illustrates a touch screen arrangement incorporating sliders, a D-pad and a raised rectangular screen;

FIG. 17a is a schematic perspective view of a portion of a trench injection optic having a straight, linearly extending front wall;

FIG. 17b is a schematic perspective view of a portion of a trench injection optic having a curved, linearly extending front wall;

FIG. 18a is a schematic perspective view of a pocket injection optic, in which the height and slope of the front wall of the recess varies about its length;

FIG. 18b is a schematic perspective view of a pocket injection optic incorporated in a lightguide having a tapered section;

FIG. 19 is a schematic perspective view of a lightguide incorporating multiple pocket injection optics, and including an absorbing mask layer on its upper surface;

FIG. 20 is a top view of a lightguide incorporating a pocket injection optic;

FIG. 21a is a side view of a portion of a lightguide incorporating a light source disposed in a recess in the underside of the lightguide;

FIG. 21b illustrates the intensity distribution of the output from a light source of the arrangement of FIG. 21a;

FIG. 21c illustrates the intensity distribution of light from the light source within the lightguide of FIG. 21a;

FIG. 22a illustrates the horizontal intensity distribution and the vertical intensity distribution of light from a wide-angle surface-mounted device LED;

FIG. 22b illustrates the horizontal intensity distribution and the vertical intensity distribution of light from a narrow-angle surface-mounted device LED;

FIG. 23a is a perspective view of an LED device incorporating a circular lens;

FIG. 23b illustrates the horizontal intensity distribution and the vertical intensity distribution of light from the device of FIG. 23a;

FIG. 24a is a perspective view of a hyper-elliptical LED package incorporating a cylindrical lens;

FIG. 24b illustrates the horizontal intensity distribution and the vertical intensity distribution of light from the device of FIG. 24a;

FIG. 24c is a plan view of the LED package of FIG. 24a;

FIG. 25a is a side view of a portion of a lightguide incorporating the LED package of FIG. 24a;

FIG. 25b is a perspective view of a portion of a lightguide incorporating the LED package of FIG. 24a;

FIG. 25c illustrates the intensity distribution of the output from the LED package of FIG. 24a in isolation;

FIG. 25d illustrates the intensity distribution of light from the light source within the lightguide of FIG. 25b;

FIG. 26 is a graph illustrating uniformity of light intensity distribution in a lightguide versus distance from a pocket injection optic in the z-direction;

FIG. 27 is a graph showing how the optical power from an LED, and the horizontal and vertical beam half-angles of the LED, varies for different LED chip sizes;

FIG. 28 is a perspective view of a lightguide having a curved profile, and incorporating sixteen pocket injection optics;

FIG. 29a is another perspective view of the lightguide of FIG. 28, and illustrates the light distribution in the lightguide;

FIG. 29b is a perspective view of a curved lightguide incorporating twelve pocket injection optics, and illustrates the light distribution in the lightguide;

FIG. 29c is a perspective view of a curved lightguide incorporating eight pocket injection optics, and illustrates the light distribution in the lightguide;

FIG. 29d is a graph illustrating the uniformity of optical power density in a side wall of each of the lightguides of FIGS. 29a-c, at different angular positions about a central axis, C, of the lightguide;

FIG. 30 is a perspective view of a lightguide having a rectangular profile, and incorporating thirty two pocket injection optics;

FIG. 31a is another perspective view of the lightguide of FIG. 30, and illustrates the light distribution in the lightguide;

FIG. 31b is a perspective view of a rectangular lightguide incorporating twenty six pocket injection optics, and illustrates the light distribution in the lightguide;

FIG. 31c is a perspective view of a rectangular lightguide incorporating twenty pocket injection optics, and illustrates the light distribution in the lightguide;

FIG. 31d is a graph illustrating the uniformity of the optical power density across the x-axis of each of the lightguides of FIGS. 31a-c;

FIG. 32 is a perspective view of a curved lightguide incorporating active and inactive zones;

FIG. 33 is a perspective view of a flat lightguide incorporating multiple active zones separated by inactive zones defined by an absorbing mask layer;

FIG. 34a is a cross-sectional side view of a curved lightguide incorporating injection optics disposed at either end, and an absorber on an end face;

FIG. 34b is a cross-sectional side view of a curved lightguide incorporating injection optics disposed at either end, and an absorber along an end wall;

FIG. 35a is a cross-sectional side view of a curved lightguide incorporating injection optics disposed at either end, and showing stray light reflected from one of the injection optics;

FIG. 35b is a cross-sectional side view of a curved lightguide incorporating injection optics disposed at either end, and an absorber extending over one of the injection optics;

FIG. 36 is cross-sectional side view of a portion of a touch sensitive device that is formed by a composite;

FIG. 37 is cross-sectional side view of a portion of another touch sensitive device that is formed by a composite;

FIG. 38 is cross-sectional side view of a portion of another touch sensitive device that is formed by a laminate;

FIG. 39 is cross-sectional side view of a portion of another touch sensitive device that is formed by a laminate;

FIG. 40 shows a curved lightguide and illustrates the radius of curvature and thickness of the lightguide for use in calculations of a dial corner curvature ratio;

FIG. 41a illustrates a pocket injection optic providing a narrow light distribution;

FIG. 41b illustrates a pocket injection optic providing a wide light distribution in a curved lightguide;

FIG. 42a shows another example of an HE-LED package incorporating an aspheric lens;

FIG. 42b illustrates the horizontal intensity distribution and vertical intensity distribution of light from the device of FIG. 42a;

FIG. 42c is a plan view of the HE-LED package of FIG. 42a;

FIG. 43 illustrates an interlayer formed of multiple sub-layers, for use as in intermediate layer in a laminate.

### DETAILED DESCRIPTION

Optical touch-sensitive lightguides that use flat lightguides and are primarily marketed as whiteboard upgrades are known. However, the market is moving in a new direction that necessitates the introduction of a thin, continuous 3D curved upper-layer to provide a single, free-flowing shape (without any mechanical elements breaking through the surface) to allow more elaborate, aesthetically pleasing styles to be realised. Safety is also a key factor and there is a need to add geometric indentations or groove features on the top surface of the upper-layer to: (a) aid finger location or guidance, and (b) allow a user to identify a relevant portion on a touch screen through touch alone, so as not to have to look where their finger is placed (i.e. ‘to keep your eyes on the road’).

In accordance with the invention, an optical touch-sensitive controller for an electronic, human display interface (HDI) 8 is described.

The apparatus of the present invention may utilise, for example, touch screen technology developed by the Applicant, and described in WO2015/155508. In the approach taught in WO2015/155508, frustrated total internal reflection is used in combination with a lossy base plate 18. Losses in transmission between entry of light into the base plate element 18 and the one or more detectors 20 associated with the base plate 18 can then be used by processing means to determine the position of a touch. Such a lossy base plate 18 may be a weak absorber of light emitted from the relevant light sources, and may be chemically doped with a weakly absorbing material for this purpose.

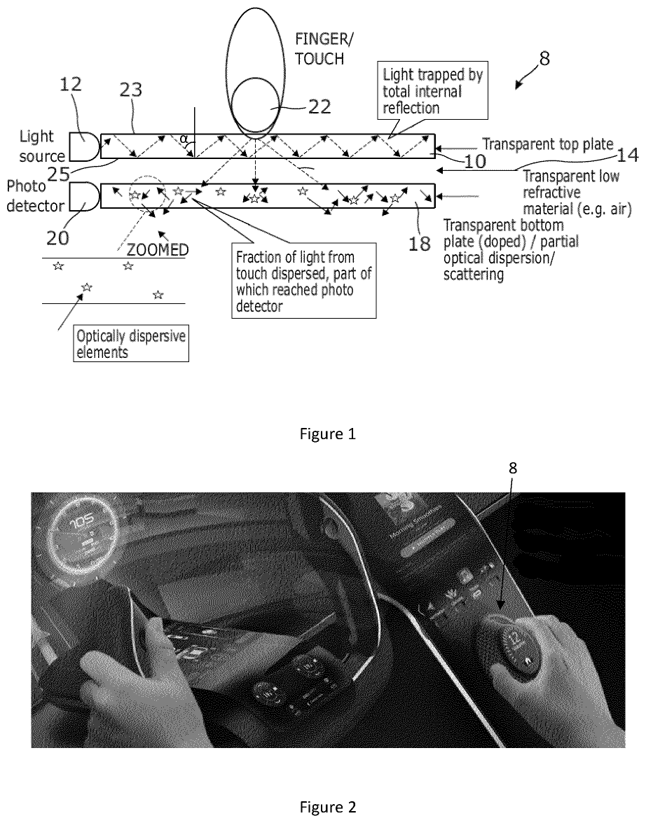

Referring to FIG. 1, which illustrates the approach taught in WO2015/155508, a HDI 8 comprises a three-layer optical laminate above one or more displays (not shown in FIG. 1). Light is coupled into a top plate or upper layer 10 of the laminate and contained within this upper lightguide 10 through total internal reflection, until a touch on a first or upper surface 23 of the upper layer 10 causes a small percentage of the light contained in the upper layer 10 to be ejected from a second or lower surface 25 of the upper layer 10 through an intermediate layer 14 (of air or a lower refractive index material) towards and through a first or upper surface 26 of a lower laminate plate 18 (i.e. a base plate 18) where the light can be detected and the finger-press position on the upper surface 23 determined. The lower laminate plate 18 is doped, and light is dispersed in the lower laminate plate 18 such that from the light detected at photodetectors 20 the finger-press position can be calculated. There may be a plurality of photodetectors 20 arrayed around the lower laminate plate 18—these can be arrayed for most effective detection of finger-press position for the geometry of the HDI 8.

It has now been found that by using new approaches to light injection, a particularly effective HDI 8 can be developed by achieving a uniform profile of light in the upper layer 10 lightguide. New methods and apparatus for injecting light into the upper layer 10 lightguide, and for shaping distribution of the injected light for the benefit of improved touch-sensitive response, are described. Methods of fabrication of the laminate structure, that are suited to high-volume manufacture, are also described. The described new 3D lightguide geometries require a new way to couple or ‘inject’ light into the top plate 10, which minimizes light-loss at geometry features, e.g. at curved portions of the top plate 10, and makes efficient use of the light available, distributing this light efficiently to where it is most needed. In addition, the new lightguide can be easily fabricated (e.g. using injection moulding techniques) and may use surface mount device (SMD) components to minimize form-factor and simplify the construction.

Inefficiency associated with edge injection of light in a lightguide is addressed by injecting light into the top plate 10 closer to the geometry where it is most needed, such that the light does not traverse longer distances than necessary before reaching active areas of the touch screen in which a touch on the upper surface 23 of the top plate 10 can be detected. Furthermore, the injected light does not disperse before it is ‘used’, i.e. within an active touch detection area of the touch screen 8. A significant aspect of efficiency is to ensure that all light that travels within the lightguide is “useful” light—that is, light that is travelling on an appropriate trajectory for the touch detection process to operate as intended. Light that is not useful in this way may not contribute to signal, but may contribute to noise—so in order to achieve best signal-to-noise, it may be more significant to prevent stray light from propagating than simply to maximise the amount of light entering the top plate 10.

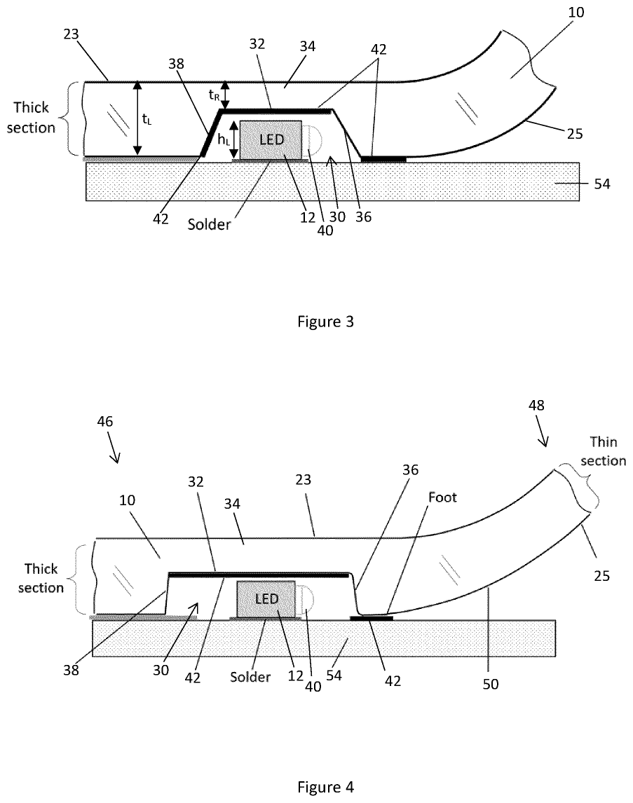

Referring to FIG. 3, means for injecting light from a light source 12 into a lightguide 10 is shown. The arrangement of FIG. 3 may, for example, be incorporated as the top plate 10 of a touch detection system 8 such as that of FIG. 1.

In this example the lightguide 10 is defined by a curved plate of constant thickness, t_{L}, where the thickness is defined as the distance between the upper surface 23 and the lower surfaces 25 of the lightguide 10. The lightguide 10 may be planar or a variety of other 3-dimensional (3D) shapes. Unlike conventional systems in which light is coupled into a lightguide 10 through an edge of the lightguide 10, in the example of FIG. 3 light is coupled into the lightguide 10 at a position inset from the edge of the lightguide 10 (although the coupling position is not limited to this position in the lightguide 10). In this way, light is coupled into the lightguide 10 at a position that is closer to the beginning of the geometry where it is needed, i.e. at a position closer to the active region of the lightguide 10 in which the light is utilised for touch detection.

As shown in FIG. 3, the lightguide 10 includes a cavity or recess 30 for receiving and housing a light source 12, which in this example is a LED. The cavity 30 is defined in the second or lower surface 25 of the lightguide 10 at the underside of the lightguide 10, and extends partially through the thickness, t_{L}, of the lightguide 10 so as not to break through the upper surface 23 of the lightguide 10. In this way, the cavity 30 extends from the lower surface 25 of the lightguide 10 towards the upper surface 23 of the lightguide 10, and terminates below the upper surface 23 such that a roof surface 32 of the cavity 30 is located between the upper and lower surfaces 23, 25 of the lightguide 10. The portion of the lightguide between the roof surface 32 and the upper surface 23 defines a roof 34 of the cavity 30. In other words, the portion of the lightguide 10 above the cavity 30 defines the roof 34 of the cavity 30 (see FIG. 4 in particular).

The cavity 30 includes a front surface 36 and a rear surface 38 that are illustrated in FIG. 3, and side surfaces (not shown in FIG. 3). The front and rear surfaces 36, 38 are sloped towards one another when moving in the direction from the lower surface 25 to the upper surface 23. In this way, the cavity 30 is tapered in width, such that the width of the cavity 30 between its front and rear surfaces or walls 36, 38 decreases moving away from the lower surface 25 of the lightguide 10 towards the upper surface 23 of the lightguide 10. It should be noted that the rear surface 38 is only required to be sloped to create a draft angle for injection moulding. Considering now the light coupling end of the cavity 30 in particular, the front wall 36 forms an angle to the plane of the lightguide or top plate 10 in the region incorporating the light source cavity 30, such that the front wall 36 and the second or lower surface 25 of the top plate 10 form an obtuse angle within the top plate 10 in order to form a refracting input face. The side surfaces slope inwardly from the lower surface 25 to the upper surface 23 in this example, although this may vary in other examples. It is possible, for example, for the side surfaces to extend vertically between the upper and lower surfaces 23, 25, although a slope is usually provided to enable injection-moulding. It should be understood that in other examples the shape of the cavity 30 may vary.

When a light source 12 is disposed in the cavity 30 as shown in FIG. 3, an emitting area 40 of the light source 12, from which light is emitted from the light source 12, faces towards the front surface 36 of the cavity 30. In this way, light is emitted from the light source 12, into the lightguide 10, through the front surface 36 of the cavity 30, which acts as a light coupling surface or wall of the cavity 30. In this embodiment, absorbers 42 in the form of light absorbing layers are provided on the roof surface 32 and the rear surface 38 of the light source cavity 30 so as to block light emitted by the light source 12 from exiting the light source cavity 30 via its upper or rear surfaces 32, 38. In this way, the absorbers 42 prevent undesirable stray light that would not reach active touch detection regions of the lightguide 10 from being emitted above, behind or to the side of the light source 12. This advantageously removes stray light that could potentially confuse the touch detection system. An absorber 42 is also provided beneath the lower surface 25 of the lightguide 10 in this example, adjacent the light source cavity 30, to prevent reflection of light from the light source 12 in this region. In this way, light that does not meet the critical angle criteria for total internal reflection may be blocked from transmission in the lightguide 10.

In the example of FIG. 3, the lightguide 10 includes one cavity 30 configured to house a single light source 12. However, it should be understood that in other examples the lightguide 10 may include multiple cavities 30, each of which may be configured to house one or more light sources 12. Furthermore, in some examples the lightguide 10 may include a single cavity 30 configured to house multiple light sources 12.

Thus, as explained above, at least one cavity 30 is cut into the underside of the lightguide 10, the cavity 30 being large enough to accommodate a single light emitter 12 or multiple light emitters 12. The size and dimensions of the light source 12 determine the size and dimensions of the cavity 30 required to accommodate the light source 12 with clearance tolerances in keeping with good mechanical design. For mass produced optical parts, injection moulding is the usual fabrication method of choice. This demands a minimum roof thickness, t_{R}, over the light source 12, which in this case takes the form of a LED, that can be reliably moulded, otherwise this can result in ‘sinks’ in the upper surface 23 of the lightguide 10 above the LED that are functionally and aesthetically unacceptable. The roof thickness, t_{R}, is defined as the thickness of the roof 34 of the cavity 30, which is defined as the distance between the roof surface 32 of the cavity 30 and the upper surface 23 of the lightguide. In the embodiment of FIG. 3, a relatively thick lightguide section is used compared to the LED height, h_{L}, such that the roof 34 of the cavity 30 has sufficient thickness, t_{R}, to accommodate the LED 12 without sinks appearing in the upper surface 23 of the lightguide 10 above the LED 12.

FIG. 4 shows another embodiment of means for injecting light from a light source 12 into a lightguide 10 for use in a touch-sensitive optical system. In this example, the lightguide 10 includes a first, relatively thick, section 46 and a second, relatively thin, section 48 (i.e. a reduced width section). The first section 46 is thicker than the second section 48. In other words, the distance between the first surface 23 and the second surface 25 of the lightguide 10 is greater in the first section 46 than in the second section 48. The light source cavity 30 is provided in the first relatively thick section 46 of the lightguide 10. A tapered section 50 of the lightguide 10, in which the distance between the first surface 23 and second surface 25 is reduced in a direction extending away from the front wall 36 of the recess 30, joins the first section 46, i.e. the thicker cavity section, to the second section 48, i.e. the thinner lightguide section.

Similarly to the light source cavity 30 of FIG. 3, the light source cavity 30 of the arrangement of FIG. 4 is defined in the lower surface 25 of the lightguide 10, and extends partially through the thickness of the lightguide 10. The cavity 30 terminates at a roof surface 32 of the cavity 30 located between the upper and lower surfaces 23, 25 of the lightguide 10, and the portion of the lightguide 10 between the roof surface 32 and the upper surface 23 defines a roof 34 of the cavity 30. The cavity 30 includes front and rear surfaces 36, 38 that are illustrated in FIG. 4, and side surfaces (not shown in FIG. 4). The front and rear surfaces 36, 38 are sloped towards one another when moving in the direction from the lower surface 25 to the upper surface 23. The cavity 30 of FIG. 4 is thus slightly tapered in width, such that the width of the cavity 30 between its front and rear surfaces 36, 38 decreases moving away from the lower surface 25 of the lightguide 10 towards the upper surface 23 of the lightguide 10, although this taper is less pronounced in the arrangement of FIG. 4 than it is in FIG. 3. The side surfaces slope inwardly from the lower surface 25 to the upper surface 23 in this example, although this may vary in other examples. It should also be generally understood that in other examples the shape of the cavity 30 may vary.

Again similarly to the arrangement of FIG. 3, an emitting area 40 of the light source 12 disposed in the cavity 30 of FIG. 4 faces towards the front surface 36 of the cavity 30, such that the front surface 36 of the cavity 30 acts as a light coupling surface. The light coupling surface 36 defines a refracting input face of the lightguide 10, at which light from the light sources 12 is refracted into the lightguide 10. Absorbers 42 are provided on the roof surface 32 and beneath the lower surface 25 of the lightguide 10, adjacent the light source cavity 30, for similar reasons to those already described in relation to FIG. 3.

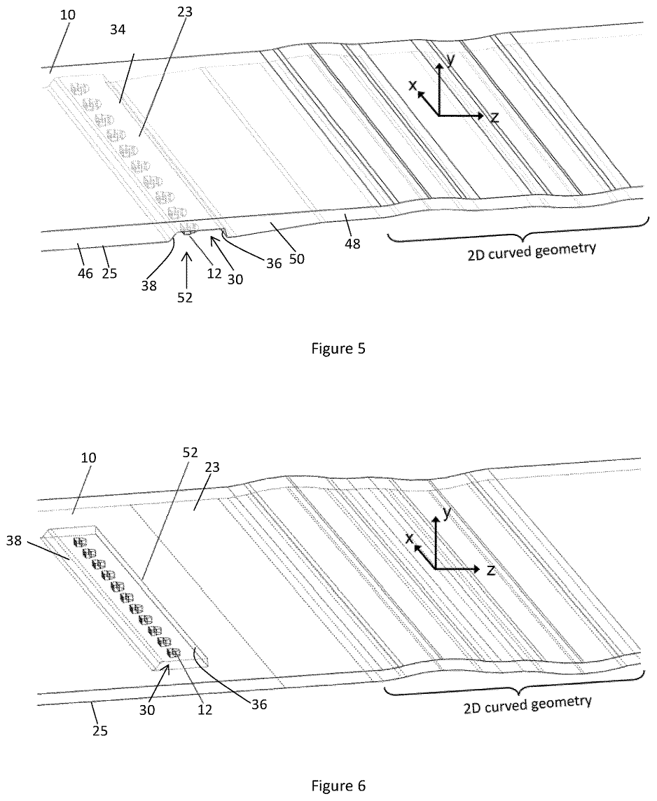

Turning now to FIG. 5, a light source cavity 30 similar to that shown in FIG. 4, but dimensioned to house multiple light sources 12 (only one or which is labelled in FIG. 5 for clarity) rather than a single light source 12, has been incorporated in a lightguide 10 having curved geometry. The lightguide 10 of FIG. 5 is curved in two dimensions, in particular in the y and z dimensions, as defined in FIG. 5. The lightguide 10 of FIG. 5 is extruded symmetrically about the x-axis as also defined in FIG. 5.

Light emitted from the light sources 12 passes through the refracting input-face 36 and passes through the taper section 50 of the lightguide 10 where it is contained in the lightguide 10 by total internal reflection. The array of light sources 12 are spaced along the length of the linearly extending recess 30 to form a linear array within the recess 30, and so as to form a substantially uniform light distribution in a body of the lightguide or top plate 10.

The light coupling surface 36 through which light is injected into the lightguide 10, as well as the tapered lightguide section 50, is configured to account for spatial and angular characteristics of the light source 12, and in particular to:
a) maximise the optical injecting efficiency from the one or more light sources 12 into the lightguide 10. This may be realised, for example, by providing an optical polish on the light coupling surface 36;
b) negate or minimise optical losses, in particular in the vertical plane, by ensuring light-rays do not fall outside of the critical-angle range at the upper and/or lower surfaces 23, 25 of the lightguide 10 (i.e. that the incident angle of rays hitting the upper/lower surface 23/25 with respect to the surface normal of the upper/lower surface 23/25 does not fall below the relevant critical angle defined with respect to the surface normal);
c) maximise the touch sensitivity of a system incorporating a lightguide 10 as described by controlling the average-ray incident-angle (with respect to the surface normal) at the upper-lightguide surface 23. Specifically, the injection optic is configured such that the average incident angle of light rays emitted from the light sources 12 and hitting the upper and lower surfaces 23, 25 of the lightguide 10 is closer to the critical angle. The incident angle, a, of rays hitting the upper/lower surface 23/25 is defined with respect to the surface normal of the upper/lower surface 23/25, as is common in the field, and as is illustrated in FIG. 1 for completeness and clarity. It has been shown that the depth of the evanescent field, i.e. penetration of the evanescent field, increases as the incident angle of a light ray undergoing total internal reflection at a boundary approaches the critical angle. Thus, configuring the injection optic such that light rays undergoing total internal reflection in the lightguide 10 propagate as close to the critical angle as possible increases the evanescent field depth, which in turn improves touch sensitivity of such a system making use of frustrated total internal reflection in the touch detection process. It will be understood that the angle between incident rays from the light sources 12 and the upper/lower surfaces 23/25 of the lightguide 10 may change as the light travels through the lightguide 10 via total internal reflection, in particular if the lightguide 10 is curved. If, for example, the angle α at which light strikes the upper/lower surface 23/25 of the lightguide 10 decreases so as to fall below the critical angle and thus fall below the angular threshold for total internal reflection, light will be lost from the lightguide 10. The vertical angular range of incident light coupled into the lightguide 10 may be chosen with this consideration in mind, so as to balance the benefit of increased evanescent field depth with light loss that occurs when the incident angle, a, of light rays falls below the critical angle. With these points in mind, it will be appreciated that the mounting of the light source 12 relative to the wall of the or each refracting face 36 may be arranged such as to refract light thereby increasing evanescent field strength while containing light within the top plate 10 through total internal reflection.
d) spread the light-rays, in particular in the horizontal plane, to optimise the uniformity of the optical power-density at the upper surface 23 of the lightguide 10, and thereby increase uniformity of the touch response across the touch sensitive area(s) of the system.
e) create an optical cavity shape that is large enough to accommodate a single or multiple light-emitting package(s) 12 depending on the application, but small enough to minimise the distance between the back of the optic cavity 30, i.e. the rear surface 38 of the light source cavity 30, and the start of the active area of the touch-surface.
f) improve the ease of manufacture of the optical cavity shape.

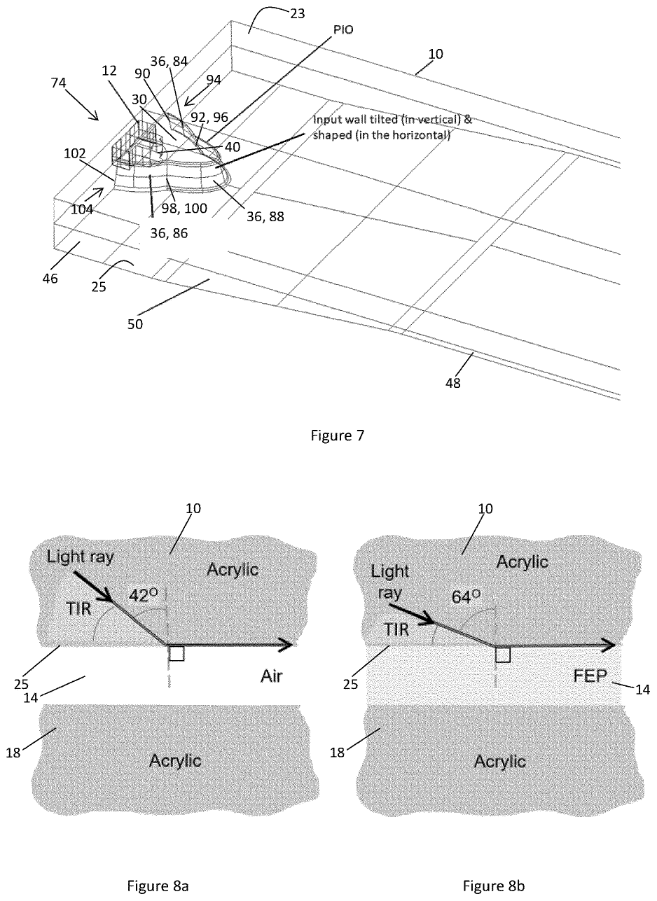

In FIGS. 5 and 6, the cavity 30 defines a linearly extending recess in the top plate 10 for receiving multiple light sources 12, and is referred to as a ‘trench injection optic’ (TIO) 52. In other embodiments the cavity 30 is dimensioned and arranged to house a single light source 12, as shown in FIG. 7, and is referred to as a ‘pocket injection optic’ (PIO) 74. Other variants are possible. In the embodiments of FIGS. 5 and 6 the linearly extending recess extends in a straight line across the lightguide 10, but it should be noted that this may differ in other embodiments. For example, in other embodiments the linearly extending recess may extend along a curved path. In some variants the cavity 30 may extend across the top plate 10 for example along conic or aspheric paths, along paths defined by splines, or along any other paths made up of a single or multiple sections that are not all listed here, but, are obvious to those skilled in the art.

It should be understood that one or more trench injection optics 52 could be combined with one or more pocket injection optics 74 within the same top plate 10, and/or more generally within the same touch sensitive apparatus or system.

Ordinarily for a flat lightguide 10 having upper and lower planar surfaces 23, 25 that extend parallel to one another, once light is coupled or ‘injected’ into the lightguide 10, the light is contained within the lightguide 10, provided the angle between the reflected light-rays and the surface-normal remains equal to or above the critical angle determined by the refractive index of the material of the lightguide 10. FIGS. 8a and 8b illustrate the path of a light ray travelling in a lightguide 10 formed of acrylic material, and striking the lower surface 25 of the lightguide 10 at the critical angle. In FIG. 8a, the lower surface 25 defines an interface between the acrylic material of the lightguide 10 and an air gap that defines the middle layer 14 between the lightguide 10 and a bottom plate 18, such that the critical angle at the interface is around 42°. In FIG. 8b, a layer of fluorinated polymer, fluorinated ethylene propylene (FEP) material is provided between the top and bottom plates 10, 18 to define the middle layer 14, such that the critical angle at the interface is around 64°.

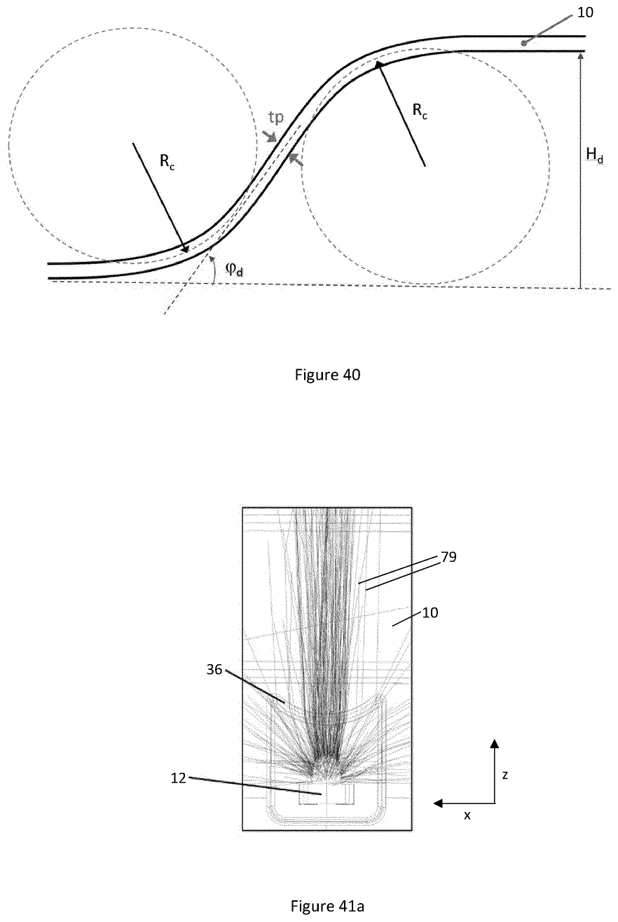

However, for a lightguide 10 having a more complex surface profile including, for example, 3D depressions or domes, additional requirements must be met to minimize light losses during propagation of light through the lightguide 10. A general rule for minimizing loss of light from a lightguide 10 when using light sources 12 having relatively small divergence angles, is that any lightguide curvature should follow a bend-radius-to-lightguide-thickness of greater than 5 to 1. That is, with reference to FIG. 40, the ratio of the radius of curvature of the lightguide 10 in a given region, Rc, and the thickness, tₚ, of the lightguide 10 in that given region should exceed 5/1. This ratio may be referred to as a dial corner curvature ratio, Kd, such that Kd=Rc/tp>5/1.

Utilising this rule is generally effective when using light sources 12 that emit light having a relatively small angular divergence, but for light sources 12 having larger source divergence angles the likelihood that at least some of the light-rays from the light source 12 fall below the relevant critical angle and light loss from the lightguide 10 occurs is increased, particularly if the lightguide 10 curves in opposite directions in quick succession, e.g. the geometry profile of the lightguide 10 undergoes an ‘S’ deviation.

In apparatus utilising optical touch detection, lost-light from the system, and in particular from the lightguide 10, is highly undesirable. Escaped light, i.e. light lost from the lightguide 10, may be reflected back into the system by a user and cause the system to falsely detect a touch. For example, the user's hand in the vicinity of the lightguide 10 may reflect escaped light back into the system even if their hand is not touching the upper surface 23 of the lightguide 10, resulting in false touch detection. Furthermore, escaped light reflected back into the system may reduce the accuracy of the finger-press location determined by the system, and may lower the overall press-response. As will be explained, this may be addressed by limiting the range of angles of the light rays that are coupled into the lightguide 10 from the light source(s) 12 so that substantially all of the light rays propagating in the lightguide 10 remain above the critical-angle throughout propagation in the lightguide 10 and do not escape from the lightguide 10 through falling below the critical angle.

Turning again to FIGS. 5 and 6, a simplified optical geometry using a trench injection optic 52 will now be considered in more detail.

The trench injection optic geometry is essentially a 2D design in the vertical plane, i.e. the y-z plane, that is extruded along the x-axis.

Rather than determine the ideal shape of the 3D geometry of the trench injection optic 52, or of the pocket injection optic (discussed in more detail later), in one go, the task can be simplified by separating out the vertical and horizontal profiles. The next section discusses how the horizontal and vertical profiles may be designed and optimised independently of each other, and then combined to realise a full 3D geometry of a trench injection optic 52.

It is recognised that the optical performance in the vertical plane is not completely independent of the geometry in the horizontal plane (or vice versa), and that a full 3D optimisation may bring out further improvements in optical performance of a trench injection optic 52. However, considering the vertical and horizontal profiles separately enables a simplified optimisation process, that results in good coupling performance of the trench injection optic 52.

Turning first to the vertical profile of the trench injection optic 52, in the y-z, plane, the key requirements for optimising the trench injection optic 52 design geometry in the vertical plane are to:
i. Maximize optical coupling efficiency into the lightguide 10;
ii. Maximise optical power-density (or evanescent field) at the top surface 23 of the lightguide 10;
iii. Minimise optical losses in the lightguide 10 (primarily caused by losses from the upper and lower lightguide surfaces 23, 25). It should be noted that light lost from the system via the roof 34 of the lightguide 10 and the rear or back wall 38 of the cavity 30, or light that hits the printed circuit board (PCB) 54 beneath the light source 12, are not included in the following analysis; and
iv. Minimise the distance between the rear or back wall 38 of the trench injection optic 52 and the active-area of the lightguide 10, i.e. the region of the lightguide 10 within which a touch to the upper surface 23 of the lightguide 10 can be detected by the system.

A number of factors (primarily related to the numerical aperture of the optical system and the refractive index of the lightguide material) may be used to control or restrict the range of ray-angles propagating within the lightguide 10 and thereby minimise light losses.

The size of the light source 12 from which light is emitted into the lightguide 10 is a key factor, and there are a number of suitable sources on the market that are ideal for this application. A LED 12 may be suitable on account of its small source size, rapid response and range of wavelengths, to name a few factors. However, it should be understood that the principals described herein apply to any suitable light source 12, and the invention is not restricted to use of LEDs 12.

To ensure a reasonable optical coupling-efficiency of light into the lightguide 10, the size of the source 12 is typically chosen to be a factor of more than 4 times smaller than the lightguide thickness. Also, depending on the application, a source 12 having a wide or narrow angular light distribution may be chosen, requiring the light-distribution to be focused or spread out accordingly. As previously noted, an objective here is to maximise the coupling of useful light into the lightguide 10, rather than simply maximising the coupling of all light (including light at an angle which will not lead to signal but which could lead to noise). The invention predominantly relates to scenarios in which a narrow angle source 12 is used, but the described techniques are equally applicable to a wide angle source 12.

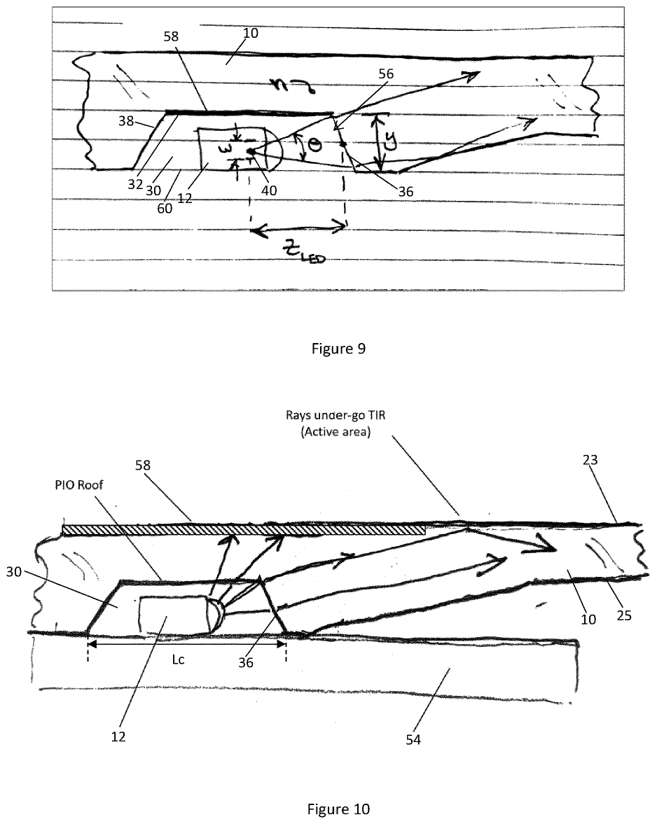

Increasing the distance between the emitting region 40 of the LED 12, i.e. the LED-tip 40, and the refracting input face 36 (for a fixed aperture width—see relevant description below) narrows the vertical angular range of rays that are coupled (or ‘injected’) into the lightguide 10 through the refracting input face 36. Referring to FIG. 9, the distance between the LED-tip 40 and the refracting input face 36 is indicated by z_{LED}, and the angular range of light rays in the vertical or z-dimension that are coupled into the lightguide 10 is indicated by θ. It will be appreciated that reducing the vertical angular ray-range, θ, reduces the optical coupling-efficiency, because light outside of the vertical angular range is not coupled into the lightguide 10. However, a benefit of reducing the vertical angular range, θ, is that this reduces the likelihood of light being lost from the lightguide 10 during passage through the lightguide 10, especially in lightguides 10 having curvature in the vertical dimension that define tight bend radii.

A further way in which the angular range of light rays coupled into the lightguide 10 may be restricted is to utilise an aperture 56. The aperture 56 may be defined using an absorbing mask 58 applied to the roof surface 32 and along a base or foot 60 of the cavity 30. The material of the absorbing mask 58 is chosen so as to absorb light in the wavelength range emitted by the associated light source(s) 12 disposed in the cavity 30. In embodiments of the invention the light sources 12 disposed in the cavity 30 may emit light in the near infra-red wavelength range, and the absorbing mask 58 may correspondingly absorb light in the near infra-red wavelength range. In some examples the absorbing mask 58 may be a black paint. One approach that can be taken, as discussed further below, is to mask only light in the “working” range for detection, but not other light, allowing such other light to be used for other purposes—for example, the masking may operate only for infra-red light, with visible light being transmitted.

It should be noted that although an absorbing mask 58 is applied to the roof surface 32 of the cavity 30 and along the base 60 of the cavity 30 to define the aperture 56 in FIG. 9, in other examples an aperture 56 may be defined by applying an absorbing mask 58 to other appropriate surfaces. For example, an absorbing mask 58 may be applied to the upper surface 23 of the lightguide 10 instead of the roof surface 32 of the cavity 30 to define the upper edge of the aperture 56, as shown in FIG. 10. The absorbing mask 58 applied to the upper surface 23 of the lightguide 10 extends far enough along the upper surface 23 to intercept rays that have passed through the cavity roof 34, but not so far as to intercept rays that would undergo total internal reflection from the top surface 23. As shown in FIG. 10, for this the absorbing mask 58 along the upper surface 23 extends over the full length, Lc, of the cavity 30, and terminates at a position offset from the cavity 30, within the tapered section 50 of the lightguide 10. As such, masking is provided for a section of the first surface 23 lying over the light source cavity 30 and extending beyond the cavity 30 to limit an angular range of light incident for reflection at the first surface 23 of the lightguide 10, from the plurality of light sources 12. Later it will be explained how a lightguide 10 having absorbing masks 58 such as those described can be achieved using either in-mould labelling (IML) or two shot moulding.

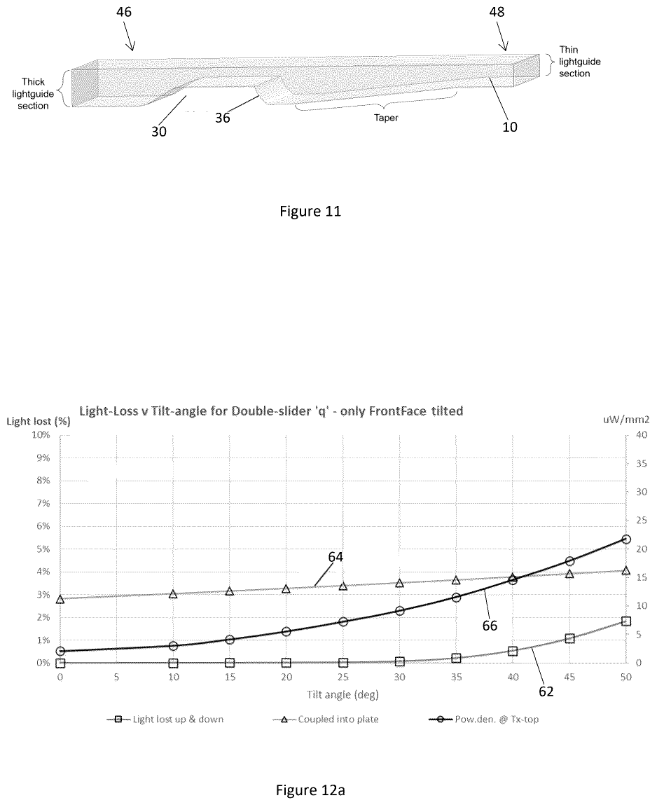

The angle and two dimensional (2D) shape of the optical surface(s) of the lightguide input cavity wall 36 used to refract (i.e. bend) the light rays can also be configured to control or restrict the range of ray-angles propagating within the lightguide 10. For example, FIG. 11 shows an example of a light source cavity 30 having a light coupling wall 36 shaped to define a symmetric lens, such that the light coupling wall 36 has convex curvature. In other words, the front wall 36 of the light source cavity 30 in this example is lensed. The symmetric lens is tilted or angled with respect to the vertical axis, y, such that the light coupling wall 36 slopes inwardly towards the light source 12 from the lower surface 25 to the upper surface 23. The symmetric lens shape is added to the input wall 36 with enough angle on the refracting input face 36 to enable this geometry to be fabricated by injection moulding. The lens of FIG. 11 helps to reduce the angular range of rays entering the lightguide 10, and in particular the vertical angular range, θ.

If incorporating the described lightguides as a top plate 10 in a system such as that of FIG. 1 using an intermediate or middle layer 14 of material [e.g. fluorinated polymer (FEP)] rather than air, then it is preferable to further restrict the angular range of light rays entering the lightguide 10 from the light sources 12, in particular the vertical angular range, θ. The higher refractive index of FEP (i.e. 1.344) compared to air (i.e. 1.0) means that the angular range of rays that exceed the critical angle at the boundary between the lightguide or top plate 10 and the middle layer 14, and thus will undergo total internal reflection, is reduced from approximately 48° (when the lightguide 10 is formed of acrylic and the middle layer 14 is air) to 26° (when the lightguide 10 is formed of acrylic and the middle layer 14 is FEP material). This is illustrated in FIGS. 8a and 8b, which show the angular range of light rays that fall within the critical angle range for a system having an intermediate layer 14 of air (FIG. 8a) and an intermediate layer 14 of FEP (FIG. 8b). Thus, it will be understood that a system such as that of FIG. 1 utilising an intermediate layer 14 of FEP requires the vertical angular range of light rays injected into the lightguide 10 from the light source(s) to be more restricted compared to a system utilising air as the intermediate layer 14, in order for substantially all of the injected light rays to fall within the angular range that enables total internal reflection of these rays at the boundary between the lightguide 10 and the intermediate layer 14. Thus, a more restricted angular range is required in a system using, e.g. FEP as an intermediate layer 14 instead of air.

It is also important to manage light from the light source that is directed downwards, towards the PCB 54 on which the light source 12 is mounted, since if this light is not absorbed then a small proportion may reflect off the PCB surface and contribute to unwanted stray light in the system.

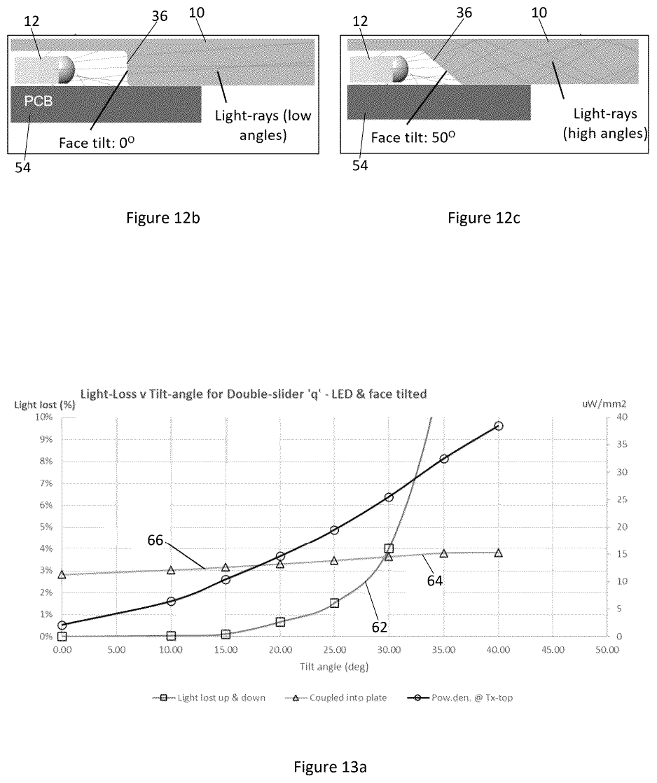

With an understanding of these factors, FIG. 12 shows that the average ray-angle in a lightguide 10 utilising a trench injection optic 52 such as that shown in FIG. 6 can be increased to maximise the evanescent field and in turn the touch-sensitivity, but, without making the extremities of the angular range too close to the critical-angle, which would result in high optical losses from the lightguide 10.

Referring to FIG. 12a, curve 62 represents the light lost from the system (y-axis) for different angles of tilt of the light coupling face (x-axis). Referring to FIGS. 12b and 12c, the tilt angle is defined as the angle of slope of the light coupling face with respect to the vertical axis, y. When the light coupling face extends vertically, as shown in FIG. 12b, the tilt angle is defined to be 0°. When the light coupling face is sloped so as to extend at an angle with respect to the vertical, the tilt angle is non-zero, as illustrated in FIG. 12c in which the light coupling surface of the lightguide has a tilt angle of 50°. It will be noted that in FIG. 12c the light source 12 is mounted such that light emitted from the light source 12 is predominantly directed obliquely towards the front wall 36 of the recess 30.

As shown in FIG. 12a, the light lost from upper and lower surfaces of the lightguide is greater for a tilt angle of 50° (FIG. 12c) than for a tilt angle of 0° (FIG. 12b). This is because increasing the tilt angle of the light coupling face from 0° to 50° decreases the incident angle at which light from the light source strikes the light coupling face, where the incident angle is defined as the angle between the light ray and the surface normal of the light coupling face. Deviation of the light rays due to refraction on passing through the light coupling face is increased in the arrangement utilising a tilt angle of 50° compared to an arrangement utilising a tilt angle of 0°, and thus the angles of the light rays with respect to the surface normal at the upper and lower surfaces of the lightguide is decreased. In this way, the likelihood that at least some light rays fall below the critical angle and are lost from the system is increased.

Curve 64 represents the light coupled into the lightguide 10 (y-axis), in units of micro-Watts (μW), for different tilt angles (x-axis), and shows that the light power coupled into the plate 10 increases as the tilt angle increases.

Curve 66 represents the power density at the upper surface 23 of the lightguide 10 for different tilt angles. Curve 66 illustrates that increasing the tilt angle increases the power density at the upper surface. Higher power density at the upper surface of the lightguide indicates a stronger evanescent field, which in turn allows for better touch sensitivity in such a system utilising frustrated total internal reflection in the touch detection mechanism.

Understanding how the parameters described above in respect of FIGS. 12a-c change with tilt angle allows for an appropriate tilt angle of the light coupling surface 36 to be chosen so as to balance the advantage of stronger evanescent field and better touch sensitivity at higher tilt angles, with the disadvantage of increased losses from the system at higher tilt angles.

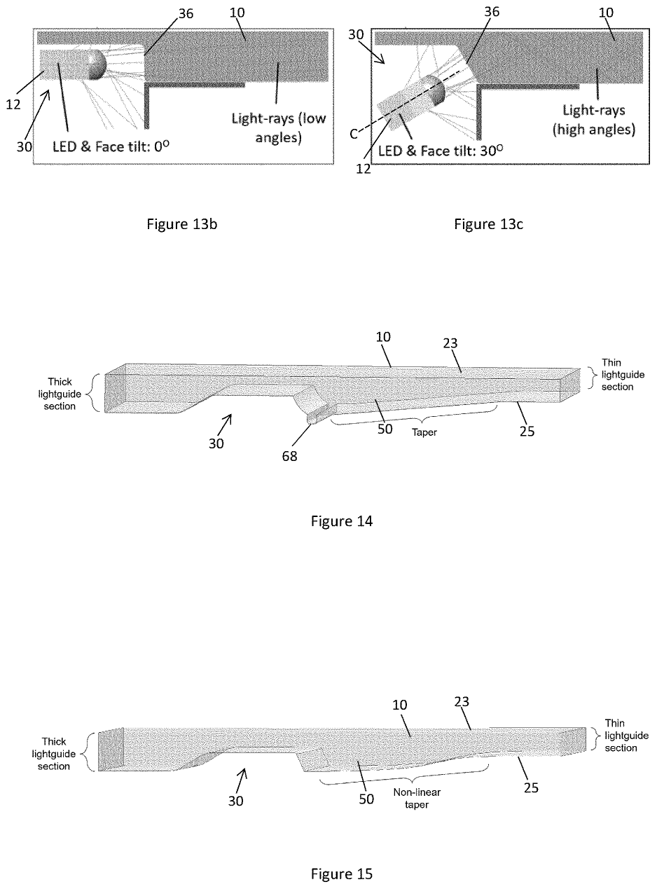

Referring to FIGS. 13a-c, in another embodiment the touch-sensitivity can be further increased by not just angling the trench wall-angle (i.e. the tilt angle of the light coupling face 36), but also by rotating the LED orientation in the yz-plane, although this does make the manufacturing more complex. Referring to FIG. 13c, the light source 12 emits light symmetrically about its central axis, C, and is mounted at an angle to a plane of the top plate 10 such that its central axis, C, is directed obliquely towards the first surface 23 of the top plate 10. Thus, light emitted from the light source is predominantly directed obliquely towards the first surface 23. Furthermore, the light source 12 is mounted such that its central axis, C, is normal to the front wall 36 of the light source cavity 30. It should be noted that in other examples the light source 12 may be mounted such that its central axis, C, is slightly offset from the axis normal to the front wall 36 of the light source cavity 30.

Referring to FIG. 14, in another embodiment an extruded section 68 is added to a lower leading edge of the wedge 50 or moat to help ‘capture’ any unwanted stray light from the bottom edge 70, to avoid a sharp edge and provide support to the lightguide 10. The extruded section 68 defines a linear protrusion on the second surface 25 of the lightguide 10, extending away from the first surface 23. As illustrated in FIG. 14, the linear extension of the linear protrusion 68 is substantially parallel to the linear extension of the light source cavity 30. In this example the linear protrusion 68 has a rectangular cross-section normal to its linear extent. In other embodiments the shape of the protrusion 68 may vary. For example, the linear protrusion 68 may have a scalloped or similar cross-section normal to its linear extent. It will be appreciated that the taper of the lightguide 10 of FIG. 14 is linear, i.e. the distance between the first and second surfaces 23, 25 of the lightguide 10 decreases linearly in the tapered section 50 of this example. Referring to FIG. 15, in another embodiment the taper of the lightguide 10 is not linear, but reduces using a faceted or other continuous non-linear function (e.g. curved, asymmetric, spline) or combination of appropriate functions. In other words, the distance between the first and second surfaces 23, 25 of the lightguide 10 decreases non-linearly in the tapered section 50 in the embodiment of FIG. 15.

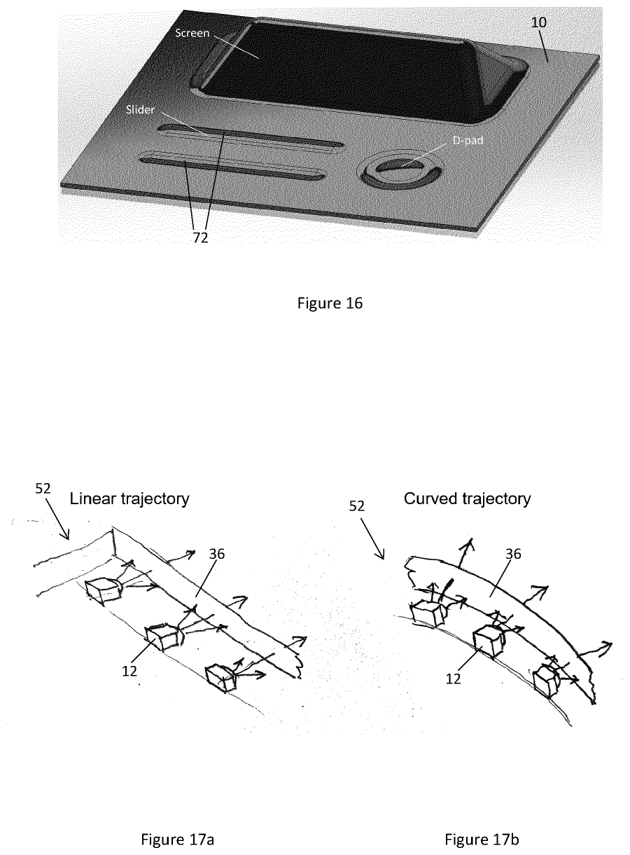

Key requirements or techniques for optimising the trench injection optic design geometry in the horizontal plane are as follows:
i. Achieve a defined optical power-density (or evanescent field) target across the top surface 23 of the lightguide 10;
ii. Achieve a defined uniformity target for the optical power-density (typically having units of μW/mm²) across the full active area of the touch-surface 23 of the lightguide 10. As noted previously, the active area of the lightguide 10 is the area of the touch surface 23 on which a touch can be detected by the system. For a touchscreen the active area could be a wide generally rectangular area, for example. For a finger-slider groove, i.e. a portion of the lightguide upper surface 23 comprising one or more grooves that act as a finger guide, the active area could be an elongate, narrow area 72, as illustrated in FIG. 16. It is beneficial to have a uniform optical power density within the active area of the lightguide 10, because this improves the uniformity of touch response across the active area;
iii. Use the least amount of sources 12 to achieve the noted uniformity target for the optical power density across the active area of the touch surface 23;
iv. Achieve the noted uniformity target for the optical power density across the active area of the touch surface 23 in the shortest possible distance from the light source(s) 12;
v. Minimise the distance between the back-face 38 of the trench injection optic 52, i.e. the rear surface 38 of the light source cavity 30, and the active-area of the lightguide 10.

The optical geometry of the trench injection optic 52 is beneficial to improve light distribution across the upper lightguide surface 23.

In a lightguide 10 utilising a trench injection optic 52 such as that shown in FIG. 5 or 6, the horizontal light distribution across the top surface 23 of the 2D curved geometry of the lightguide 10 is primarily derived from the LED light distribution and the source array layout, i.e. the arrangement of the light sources 12 disposed within the cavity 30 of the trench injection optic 52.

The light source array layout refers to the spacing and orientation of the light sources 12 in the light source cavity 30. The trajectory of the LED output can further be varied by adjusting the geometry of the light source cavity 30, and in particular the shape of the light coupling face 36. Referring to FIG. 17a, an embodiment of a trench injection optic 52 having a flat, planar light coupling face 36 is shown. Referring to FIG. 17b, an embodiment of a trench injection optic 52 having a curved light coupling face 36 is shown. In particular, the light coupling face 36 of the embodiment of FIG. 17a is curved with respect to the x-direction, to define a curve in the x-z plane.

In general, the uniformity of light within the lightguide 10 from the light sources 12 will improve the further away the LED array is from the touch geometry. In other words, the uniformity of light within the lightguide 10 improves with increasing distance from the light sources 12 of the trench injection optic 52, such that the uniformity of light in the active area improves with increasing distance of the active area from the light sources 12.

However, in many applications it is advantageous for the active area to be closer, and in some cases as close as possible, to the light sources 12 of the lightguide 10, either for aesthetic reasons of the final touchscreen product, or with space considerations/restrictions in mind. The ideal is to minimise the separation of the array from the geometry and to maximise the spacing between source 12 neighbours at which the uniformity target is met.

Masking, i.e. the use of absorbing mask layers 58 or elements to absorb light, is used in embodiments to absorb light rays hitting the upper or lower surface 23, 25 of the lightguide 10. In other words, regions of the first or upper surface 23 and/or the second or lower surface 25 may be masked to prevent total internal reflection of light within the lightguide 10, from the plurality of light sources 12 in the trench or recess 36.

The masking layers 58 or elements may be arranged so as to control the position at, for example, the upper surface 23 at which light rays are permitted to reflect from the upper surface 23, which in turn allows for light rays emitted from the light source 12 at such an angle that they would not undergo total internal reflection from the top surface 23 to be absorbed, thereby controlling light leakage from the upper surface 23 of the lightguide 10. Since the source intensity distribution can vary with angle in the xz-plane the mask edge may correspondingly vary with angle in the xz-plane.

The trench injection optic 52 approach discussed above may allow for flexibility in source component placement in embodiments in which no lensing used to couple light emitted from the light sources 12 into the lightguide 10. This is because, in that case, the exact position and orientation of each light source 12 within the cavity 30 is less critical than it would be if light from the light sources 12 were to propagate through lenses before entering the lightguide 10.

Thus, the impact of variation in source component placement (for example due to assembly tolerances) on optical performance (e.g. irradiance distribution or optical efficiency) of an array of trench injection optics 52 can be reduced when no lensing is used.

An approach for light injection into a light guide 10 utilising a pocket injection optic (PIO) 74 will now be described.

Examples of pocket injection optics 74 are illustrated in FIGS. 7, 18, 19 and 20, for example.

The pocket injection optic 74 is constructed using a full 3D geometry to control both the horizontal and vertical angular distribution of light from the light source 12. For this, the 3D shape of the light source cavity 30 in which the light source 12 is disposed is designed to control the angular distribution of light coupled into and travelling in the lightguide 10. This optical design of the pocket injection optic 74 controls the light distribution in the vertical (y-dimension) in a similar manner to the trench injection optic 52, and provides additional control over the intensity distribution in the horizontal (x-dimension) which can be used to account for differences in the vertical intensity distribution with angle, as well as to affect the convergence or divergence of the light distribution across the surface 23 of the active-area of the lightguide 10.

Considering first the vertical profile of the pocket injection optic 74, in the y-z, plane, the key requirements for optimising the pocket injection optic design geometry in the vertical plane are the same as the trench injection optic 52, which are reiterated below for clarity and completeness:
i. Maximize optical coupling efficiency into the lightguide 10;
ii. Maximise optical power-density (or evanescent field) at the top surface 23 of the lightguide 10;
iii. Minimise optical losses in the lightguide 10 (primarily caused by losses from the upper and lower lightguide surfaces 23, 25). It should be noted that light lost from the system via the roof 34 of the lightguide 10 and the rear or back wall 38 of the cavity 30, or light that hits the printed circuit board (PCB) 54 beneath the light source 12, are not included in the following analysis; and
iv. Minimise the distance between the rear or back wall 38 of the trench injection optic 52 and the active-area of the lightguide 10, i.e. the region of the lightguide 10 within which a touch to the upper surface 23 of the lightguide 10 can be detected by the system.

All the previous factors discussed for the trench injection optic 52 (primarily related to the numerical aperture of the optical system and refractive index of the lightguide material) apply for the pocket injection optic 74 also, and will not be repeated again for conciseness. Here, we only highlight the main additional factors that can be used to control or restrict the range of vertical ray-angles propagating within the lightguide 10 and thereby optimise the key requirements above.

The angle, shape and taper of the refracting input face 36 (also referred to as the light coupling face 36 of the light source cavity 30) can be used to control the vertical angular range of light rays propagating within the lightguide 10. As discussed in relation to the trench injection optic 52, the depth of the evanescent field, i.e. penetration of the evanescent field, increases as the incident angle of light rays undergoing total internal reflection at a boundary between two regions of different refractive index material approaches the critical angle. Thus, configuring the injection optic 52, 73 such that light rays propagate in the lightguide 10 at angles as close to the critical angle as possible increases the evanescent field depth, which in turn improves touch sensitivity of such a system making use of frustrated total internal reflection in the touch detection process.

As discussed in relation to FIGS. 12b and 12c, increasing the angle of the light coupling face 36 with respect to the vertical (y) axis (i.e. the slope or tilt of the refracting input face 36) can be used to increase the evanescent field at the upper surface 23 of the lightguide 10, by ensuring that light from the light sources 12 within the lightguide 10 propagates as close to the critical angle as possible. In a similar way, the inclusion of a tapered section 50 in the lightguide 10, between a thicker section 46 comprising the light source cavity 30 and a thinner section 48, can be used to increase the evanescent field at the upper surface 23 of the lightguide 10, as can adjustment of the taper of the tapered section 50, or some combination thereof. However, in the pocket injection optic 74, these parameters can be varied in side portions of the light coupling face 36 extending back towards the rear of the light source cavity 30, for example to compensate for variations in the source intensity distribution.

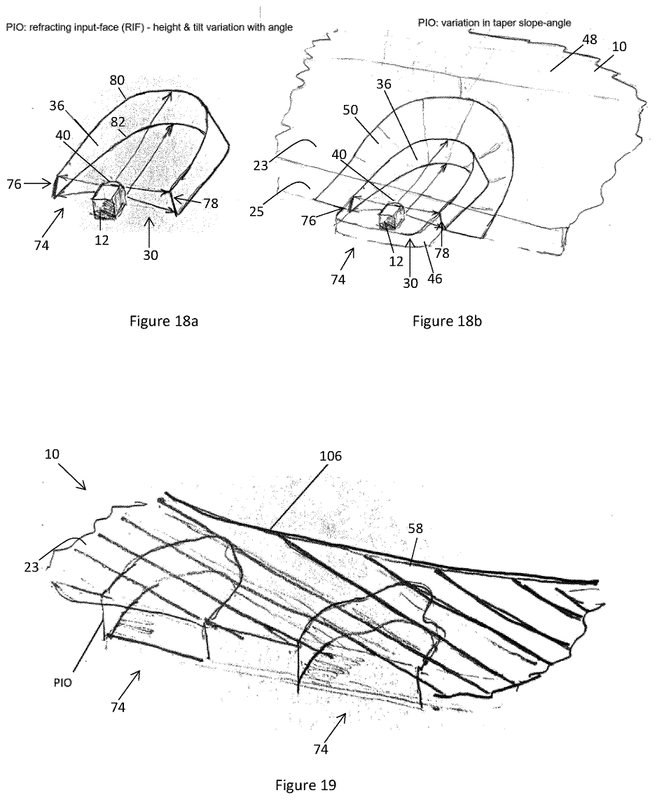

FIG. 18a shows an embodiment of a pocket injection optic 74 that may, for example, be incorporated in the top plate 10 of a touch detection system such as that of FIG. 1.

Similarly to the trench injection optic 52 arrangements of FIGS. 5 and 6, the pocket injection optic 74 of FIG. 18a includes a cavity or recess 30 in the underside of the lightguide defined by the top plate 10. The cavity 30 has a light coupling face 36 that acts as a refracting input face for coupling light from a light source 12 disposed in the cavity 30 into the body of the top plate 10.

In the embodiment of FIG. 18a, the refracting input face 36 defines a curved path between first and second ends 76, 78 of the refracting input face 36, defining a curved length between the first and second ends 76, 78. The refracting input face 36 extends about the light source 12 from the first end 76 to the second end 78, so as to partially surround the light source 12. The front face of the light source 12 defines an emitting area 40 of the light source that faces the refracting input face 36 of the cavity 30. In use, light is emitted from the emitting area 40 of the light source 12, and passes through the refracting input face 36 and into the body of the top plate 10 in which the light undergoes total internal reflection.

Referring still to FIG. 18a, the height of the refracting input face 36, i.e. the distance between upper and lower edges 80, 82 of the refracting input face 36, varies along the curved path between first and second ends 76, 78 of the refracting input face 36. In particular, in the embodiment of FIG. 18a the height of the refracting input face 36 increases from a minimum height at the first and second ends 76, 78, to a maximum height at a position located centrally along the length of the refracting input face 36, between the first and second ends 76, 78.

The tilt or slope of the refracting input face 36 also varies along the curved path between the first and second ends 76, 78 of the refracting input face 36 in the arrangement of FIG. 18a. In particular, the tilt of the refracting input face 36 increases from the first end 76 to a central position along the curved length of the refracting input face 36. Similarly, the refracting input face 36 increases from the second end 78 to a central position along the curved length of the refracting input face 36.

In other examples, the height and tilt of the refracting input face 36, and the variation in the height and tilt of the refracting input face 36 between first and second ends 76, 78, may differ from the arrangement of FIG. 18a. In some examples the height and tilt of the refracting input face 36 may be constant across the curved length of the refracting input face 36. The parameters defining the shape and arrangement of the refracting input face 36 may be varied in dependence on parameters of the associated light source 12, for example.

FIG. 18b shows the pocket injection optic 74 of FIG. 18a incorporated in a top plate 10 having a tapered section 50 between a thicker section 46 incorporating the light source cavity 30 and a thinner section 48 of the top plate 10. In the example of FIG. 18b, the lower surface 25 of the top plate 10 surrounding the light source cavity 30 slopes upwardly from the thicker section 46 to the thinner section 48, towards the upper surface 23 of the top plate 10, to define the tapered section 50 of the top plate 10. In the embodiment of FIG. 18b, the slope of the lower surface 25 is greater adjacent the centre of the curved length of the refracting input face 36 than at the first and second ends 76, 78 of the refracting input face 36. As such, the taper of the top plate 10 is greater directly in front of the light source 12, and in particular the emitting area 40 of the light source 12, than at sides of the light source 12.

Turning now back to FIG. 7, the pocket injection optic 74 of this embodiment comprises a light source cavity or recess 30 having multiple refracting input faces 36. The pocket injection geometry has the same basic control of the light distribution in the vertical as the trench injection optic 52, but with additional control over the intensity distribution in the horizontal which can be used to account for differences in the vertical intensity distribution with angle, as well as to affect the convergence or divergence of the light distribution across the surface of an active-area in which a touch can be detected. It should be recognised that different touch geometries may require pocket injection optics 74 with narrow or wide light distributions.

FIG. 41a illustrates a pocket injection optic 74 providing a narrow distribution of light. The pocket injection optic 74 of FIG. 41a includes a single refracting input face 36 having convex curvature in the x-z plane. On passing through the refracting input face 36, the horizontal distribution of light (represented by a plurality of light rays 79 in FIG. 41a, only two of which are labelled in FIG. 41a for clarity) emitted from the light source 12 is shaped by the refracting input face 36 so as to provide a narrow distribution of light in the lightguide 10. Such a narrow light distribution may be appropriate, for example, in an elongate, narrow active area, such as that utilised for a slider 72 such as that shown in FIG. 16.

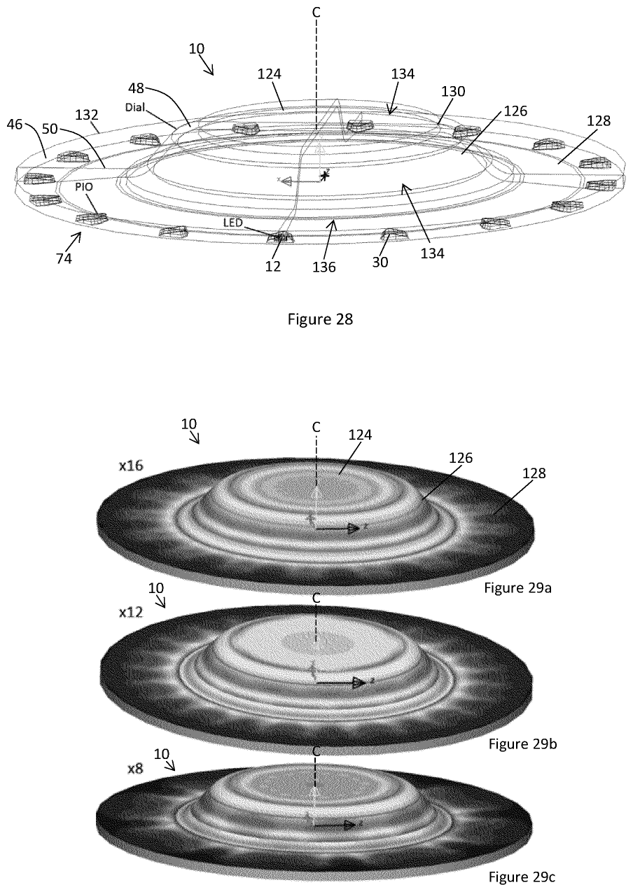

FIG. 41b illustrates a pocket injection optic 74 providing a wide distribution of light. The pocket injection optic 74 of FIG. 41b has a similar configuration to that shown in FIG. 7, having three refracting input faces 36 that act to shape the horizontal distribution of light (represented by a plurality of light rays 79 in FIG. 41b, only two of which are labelled for clarity) from the light source 12, so as to provide a broad distribution of light in the lightguide 10. Such a broad light distribution may be appropriate, for example, for use in a dial set up such as that shown in FIG. 28.

The example of FIG. 7 comprises a first side refracting input face 84, a second side refracting input face 86 and a central refracting input face 88. A light source 12 is disposed in the recess 30, such that light is coupled into the body of the top plate 10 through the refracting input face 36. The light source cavity 30 is provided in a first, relatively thick, section 46 of the lightguide 10. A tapered section or wedge 50 of the lightguide 10 joins the first section 46 to a second, thinner (or reduced width) section 48 of the lightguide 10, and lies between the recess 30 and the reduced width section 48. In the reduced width section 48, the distance between the first surface 23 and the second surface 25 is substantially constant, but is less than the distance between the first surface 23 and the second surface 25 at the recess 30.

The first side refracting input face 84 extends along a curved path between first and second ends 90, 92 of the first side refracting input face 84. The first end 90 of the first side refracting input face 84 is positioned at a first side 94 of the light source 12 when the light source 12 is disposed in the cavity 30 for use. The central refracting input face 88 extends along a curved path between first and second ends 96, 98 of the central refracting input face 88, and joins the first and second side refracting input faces 84, 86. The second side refracting input face 86 extends along a curved path between first and second ends 100, 102 of the second side refracting input face 86. The second end 102 of the second side refracting input face 86 is positioned at a second side 104 of the light source 12 when the light source 12 is disposed in the cavity 30 for use. The central refracting input face 88 is located directly in front of the front face of the light source 12, such that the emitting area 40 of the light source 12 faces the central refracting input face 88.

In this example, the two side refracting faces 84, 86 are disposed symmetrically about and adjacent to the central refracting input face 88. As will be appreciated from FIG. 7, the central refracting input face 88 has different curvature from the side refracting faces 84, 86 in this example.

In this way, light emitted from the light source 12 in a generally forwards direction in front of the light source 12 is coupled into the body of the top plate 10 via the central refracting input face 88, and light emitted in generally sidewards directions from the light source 12 is coupled into the top plate 10 via the first and second side refracting input faces 84, 86. The provision of side refracting input faces 84, 86, or wings extending from the central refracting input face 88, provides for better control of the intensity distribution of light from the light sources 12 in the lightguide 10.

The refracting input faces 84, 86, 88 are tilted inwardly towards the light source 12, from the lower surface 25 of the lightguide 10 to the upper surface 23 of the lightguide 10, in a similar manner to that shown in FIGS. 12c and 15, for example. In other words, the walls of the refracting input faces each form an angle to the plane of the top plate 10 such that the refracting input faces 84, 86, 88 and the second surface 25 of the top plate 10 form an obtuse angle within the top plate 10.

As discussed in relation to FIG. 12c, providing a tilted input face 84, 86, 88 allows for the vertical angular range of the light rays propagating in the lightguide 10 to be controlled, and in particular can be utilised to push the angles of the light rays towards the critical angle, for improved evanescent field penetration at the upper surface 23 of the lightguide 10 and improved touch sensitivity.

The curvature along the length of the refracting input faces 84, 86, 88 provide for control of the horizontal spread of light rays in the x-z plane of the lightguide 10. The different geometries, and in particular the different horizontal curvatures of the first side refracting input face 84, the second side refracting input face 86 and the central refracting input face 88 in the x-z plane, allow for enhanced control of the horizontal distribution in the lightguide 10 of light rays from the light source 12.

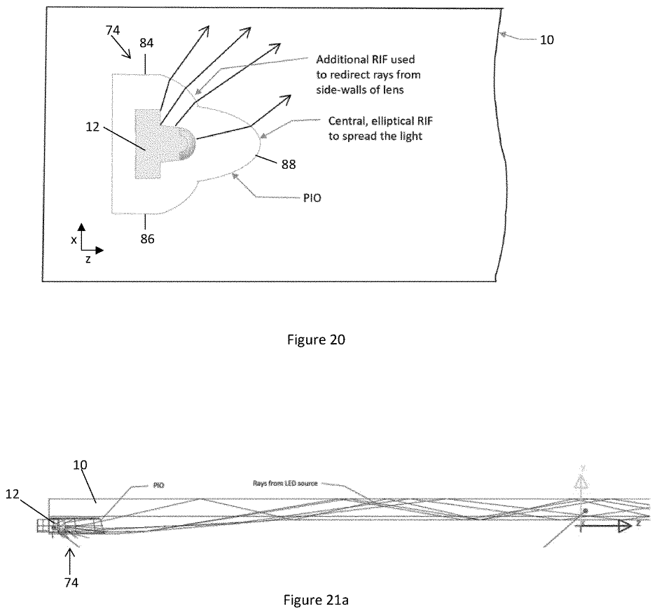

In the example of FIGS. 7 and 20, the curvature of the central refracting input face 88 defines a generally elliptical shape in the horizontal, or x-z, plane of the lightguide 10. In particular, the central refracting input face 88 defines a semi-ellipse, or half-ellipse, in the horizontal plane, with the horizontal distance in the x-dimension between first and second ends 96, 98 of the central refracting input face 88 defining the minor axis of the ellipse. The central refracting input face 88 is configured to spread light emitted from the light source 12 and incident on the central refracting input face 88 in the horizontal (x-z) plane of the lightguide.

The curvature of the first and second refracting input faces 84, 86 in the horizontal plane is chosen so as to redirect light rays hitting these portions as appropriate. In the embodiment of FIGS. 7 and 20, the first and second refracting input faces 84, 86 are configured to restrict the horizontal spread in the lightguide 10 of the light hitting these portions, as illustrated in FIG. 20.

It should be noted that the curvature of the refracting input faces 84, 86, 88 may vary in other embodiments. For example, one or more of the refracting input faces 84, 86, 88 may have a conical curvature, or define a spline. FIG. 19 shows a top plate 10 incorporating two pocket injection optics 74 having a similar shape to that of FIG. 7, and illustrates that an absorbing mask layer 58 may be provided on the upper surface 23 of the lightguide 10 to prevent stray light from the light sources 12 from escaping the lightguide 10, similarly to the masks 58 of FIGS. 3, 4 and 10. As explained previously, masking as shown in FIG. 19 is used to control light leakage from the lightguide 10, and in particular blocks light rays that fall below the critical angle in the masked region and thus would otherwise pass directly through and out of the upper surface 23 of the lightguide 10. In the embodiment of FIG. 19, a front edge 106 of the mask 58 terminates before the first totally internally reflected rays strike the upper-lightguide surface 23 and defines the start of the active area of the lightguide 10, in which a touch on the upper surface 23 of the lightguide 10 can be detected. In other words, substantially all of the light from the light sources 12 that strikes the masked region of the upper surface 23 of the lightguide 10 falls below the critical angle, and would escape the lightguide 10 without inclusion of the mask 58. Thus, the mask 58 does not absorb ‘useful’ light that would undergo total internal reflection at the upper surface 23 in the absence of the mask 58. As indicated before, one possibility is to mask only light in the “working” range for detection, but not other light, allowing other light to be used for other purposes—for example, the masking may operate only for infra-red light, with visible light being transmitted.

In the example of FIG. 19, the masking 58 is shown to extends over two pocket injection optics 74. It will be understood that in some examples masking 58 may be provided over all pocket injection optics 74 of a lightguide 10, or just some pocket injection optics 74 of a lightguide 10. Furthermore, in some example masking may extend only partially over some or all of the pocket injection optics 74 of a lightguide 10. Key requirements or techniques for optimising the pocket injection optic design geometry in the horizontal (x-z) plane are the same as those discussed in relation to the trench injection optic 52, as follows:
i. Achieve a defined optical power-density (or evanescent field) target across the top surface 23 of the lightguide 10;
ii. Achieve a defined uniformity target for the optical power-density (μW/mm²) across the full active area of the touch-surface 23 (which for a screen could be a wide rectangular area, but for a finger-slider groove could be a long, narrow area, see FIG. 16);
iii. Use the least amount of sources 12 to achieve the noted uniformity target;
iv. Achieve the noted uniformity target in the shortest possible distance from the light source(s) 12;
v. Minimise the distance between the back-face 38 of the pocket injection optic 74 and the active-area.

However, the horizontal profile control in the 3D geometry of the pocket injection optic 74 allows for direct control of the horizontal intensity distribution from the light source 12 using key control parameters.

Single, or multiple refracting input face optic profiles are used in the pocket injection optic 74 to spread or collimate the light distribution to suit the required application. FIG. 20 shows the multiple refracting input face geometry of FIGS. 7, 19 and 20, having three distinct portions (first side refracting input face 84, second side refracting input face 86 and central refracting input face 88) having different geometric profiles, incorporated in a top plate 10 of a touch sensitive screen in which a broad light distribution is required.

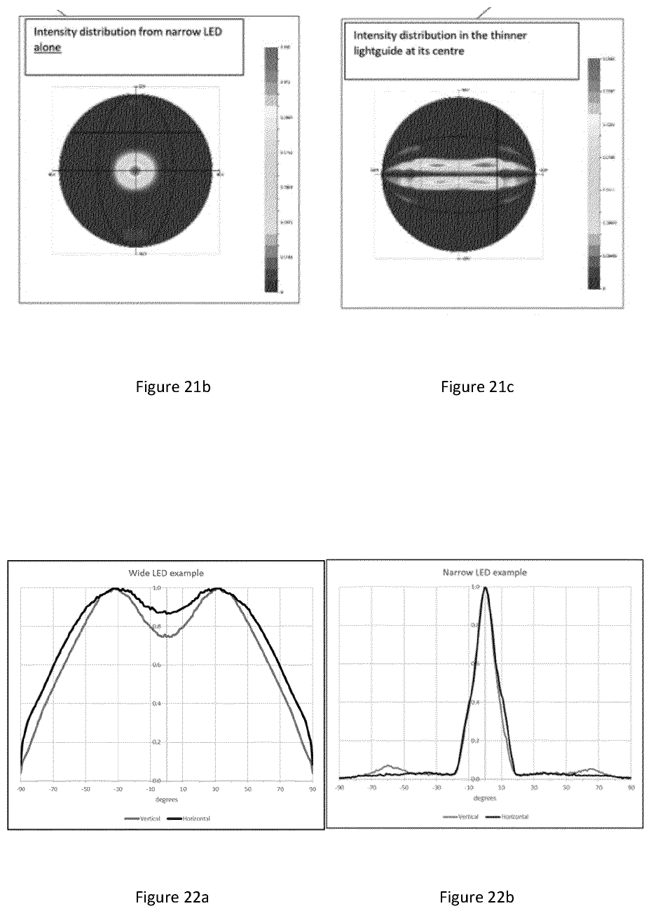

FIG. 21a illustrates the pocket injection optic 74 of FIG. 20, and shows the light rays from the light source 12 propagating in the lightguide 10 to provide a broad intensity distribution in the horizontal (x-z) plane at an active area of the lightguide 10.

FIG. 21b illustrates the narrow horizontal intensity distribution of the output from the light source 12 of the arrangement of FIG. 21a alone, before passing through the refracting input faces 84, 86, 88 of the pocket injection optic 74. FIG. 21c illustrates the intensity distribution of light from the light source 12 within the lightguide 10, in the active area of the lightguide 10 located in the thinner region 48 of the lightguide 10, after passing through the refracting input faces 84, 86, 88 of the pocket injection optic 74. As will be appreciated from FIG. 21c, the refracting input faces 84, 86, 88 broaden the horizontal intensity distribution of light from the light source 12, to provide the broad intensity distribution in the horizontal plane illustrated in FIG. 21c. Thus, FIG. 21c illustrates the resulting broad intensity distribution in the horizontal (x-z) plane of the lightguide 10 produced through use of the pocket injection optic 74 of FIG. 21a.

It will be appreciated that other geometries may be utilised for the refracting input face or faces of a pocket injection optic 74 to provide different horizontal light distributions as required or desired to match the touch-geometry for a particular touch screen application.

The shape of the refracting input wall (i.e. the refracting input face(s)) of the pocket injection optic 74 advantageously provides direct control over the xz intensity distribution in the lightguide 10 and enables an array of pocket injection optics 74 to provide improved uniformity, particularly when close to the light source 12. An array of pocket injection optics 74, each providing bespoke horizontal and vertical shaping of light from their associated light source 12, can provide improved uniformity and control of the horizontal intensity distribution when compared to an equivalent array of trench injection optics 52. In general, the improved finesse in the angular light distribution afforded by the pocket injection optic 74 approach permits the same uniformity to be achieved with less light sources 12.

A further advantage of the pocket injection scheme is that the available optical power from the light sources 12 can be used much more efficiently (and the electrical power consumption is less) since the light is distributed to where it is needed, i.e. active areas of the lightguide 10, and is not wasted in regions of the lightguide 10 where it is not needed.

The pocket injection optic 74 further allows for more flexibility in positioning of light sources 12, due to its compact size, which provides more space for other optical or mechanical features or electrical parts or components.

Furthermore, if one source 12 fails in an array of pocket injection optics 74, the combined light distribution is less affected compared to a trench injection optic 52 array, since all the pocket injection optics 74 may have the same light distribution. Equally, any inherent LED differences in an array of pocket injection optics 74 are less significant. For example, if the optical output of one light source 12 significantly differs from that of neighbouring light sources 12 in an array of pocket injection optics 74, then the impact on the light distribution may be less when compared to a similar scenario in a trench injection optic 52 having an array of light sources 12.

In some cases, it may be desirable to provide a combination of trench injection optics 52 and pocket injection optics 74 in a single device. For example, a device may be provided with separate “active zones” masked off from each other—in effect creating multiple devices or sub-devices—and different optics types may be used for each, suiting the overall functionality of the relevant active zone. For other device types, it may be desirable to use both trench injection optics 52 and pocket injection optics 74 to provide effective light transmission across the entire device—this may apply particularly where the shape of an active zone is complex.

It will be understood by the skilled person that placement of the light source 12 relative to the refracting input face(s) 36, 84, 86, 88 will affect the shaping provided by the refracting input face(s) 36, 84, 86, 88 of the pocket injection optic 74, and so this should be considered when positioning the light source 12 in the light source cavity 30. There are certain key advantages to using the trench injection optic 52 or pocket injection optic 74 geometries discussed so far with small, surface mounted device (SMD) light source (e.g. LED) packages. The smaller the light source package, the smaller the light source cavity 30 volume required in the underside of the lightguide 10, and the less intrusive the light source 12 and associated cavity 30 is to other functional elements in the assembly. However, it has been found that the light distributions from some LEDs 12 are not ideal and may result in lower efficiency and uniformity.

Applications for light sources 12 (and LEDs in particular) used in touchscreens can, in general, be divided into two groups related to their light intensity angular distribution. LEDs 12 having a wide angular range in the horizontal and a narrow angular range in the vertical are best suited to applications in which the area to be illuminated is wide, e.g. for screen, dome or dial geometries. The intensity distribution in these cases should have a ‘soft’ edge so that any overlap with adjacent pocket injection optics 74 produces a uniform irradiance distribution.

LEDs 12 having a narrow angular range in the horizontal and a narrow angular range in the vertical are best suited to applications in which the area to be illuminated is narrow, e.g. for slider and toggle geometries. In these cases, it is acceptable for the intensity distribution of the LEDs 12 to have a ‘hard edge’, since the geometries are usually illuminated by at least one pocket injection optic 74 at each end of the geometry, and there is no need to overlap the light distributions of neighbouring LEDs 12.

It should be noted that the intensity distribution forward direction is aligned along the z-axis (as defined using the co-ordinate system in FIG. 5), and the noted intensity distributions are symmetrical about the y-z and x-z planes.

SMD LEDs in the current market place that are suited to use in a pocket injection optic 74, for example, fall generally into two groups.

Referring to FIG. 22a, wide-angle SMD LEDs have intensity distributions that are wide, ‘batwing’ shaped in both the horizontal (x-z) plane and the vertical (x-y) plane.

The wide, gently sloping ‘soft edges’ of the horizontal profile of FIGS. 22a provide a good starting point for achieving reasonable uniformity in the horizontal plane, and can be improved further when combined with a pocket injection optic 74 having the appropriate horizontal lens profile on the refracting input face(s) 36, 84, 86, 88 i.e. the appropriate geometry in the x-z plane for appropriate horizontal beam shaping.

In the vertical profile of FIG. 22a, however, the wide distribution does not match well to the numerical aperture of the pocket injection optic 74, even with an appropriate horizontal profile of the refracting input face(s) 36, 84, 86, 88. This results in poor optical coupling efficiency into the lightguide 10 with which the pocket injection optic 74 and LED source 12 is incorporated.

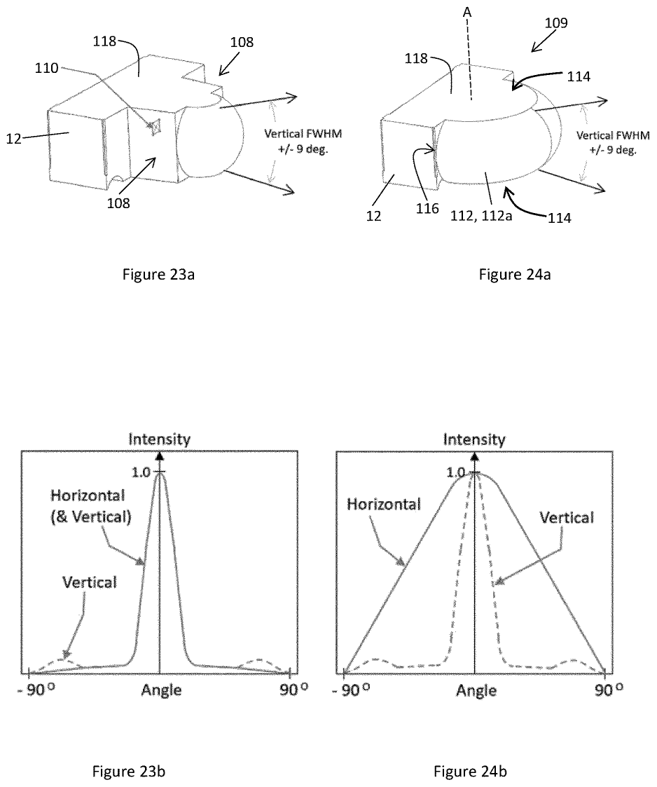

Referring to FIGS. 22b and 23b, narrow-angle SMD LEDs have intensity distributions that are narrow in both the horizontal (x-z) plane and the vertical (x-y) plane. With reference to FIG. 23a, this type of LED uses a circular lens which focuses a proportion of the light from the LED chip. Light that is missed from this focusing effect creates a ‘halo’ of high-angle rays surrounding the central narrow angular cone of rays. Through appropriate adjustment of the distance of the LED 12 from the refracting input face(s) 36, 84, 86, 88, the narrow cone of rays from the LED 12 can be matched to the numerical aperture of the pocket injection optic 74 in the vertical plane. In the horizontal plane, the narrow cone of rays can be spread using a conic profile on the pocket injection optic 74 which has been shown to give the desired light-distribution in the lightguide 10. However, the halo of light emitted through side-walls 108 of the LED 12 results in poor optical coupling efficiency and issues with stray-light management in the assembly.

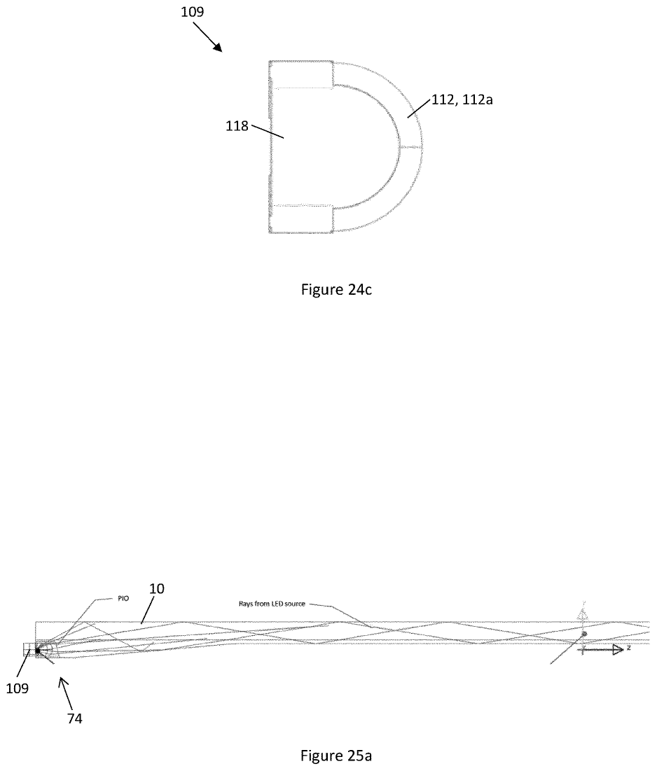

With the above in mind, FIG. 24a shows a hyper-elliptical LED package (HE-LED) 109 design. The package 109 may be used, for example, in combination with a pocket injection optic geometry having no optical power, such that the refracting input face 36 has no lensing effect for light received from the light source 12), referred to as 0%-PIO. The package 109 may also be used in combination with other injection optic geometries, for example those having optical power, such that the front wall 36 through which light passes from the light source 12 into the lightguide 10 provides a lensing effect. The front wall 36, for example, may be configured to provide a lensing effect in the horizontal dimension, the vertical dimension, or both, to provide improvements in horizontal and/or vertical light distribution in the lightguide 10 as required.

The packaged light emitting diode 109 of FIG. 24a includes a light emitting diode die or chip 110 and a lens 112. The lens 112 takes the form of a cylindrical lens 112, which acts to significantly improve the optical coupling efficiency between the light source 12 and the lightguide 10, as well as the uniformity of light in the lightguide 10. Light emitted through the cylindrical lens 112 has a narrow angular distribution along a first axis and a broad angular distribution along a second axis orthogonal to the first axis. As such, the packaged light emitting diode 109 of FIG. 24a is ideally suited to touch screen applications.

As shown in FIG. 24a, in this example the cylindrical lens 112 is formed as a truncated substantially oblate ellipsoidal lens 112a in a body having two first truncations 114 and one second truncation 116. The two first truncations 114 are normal to the axis, A, of the oblate ellipsoid and equidistant from its longest semidiameter. The second truncation 116 is parallel to the axis, A, of the oblate ellipsoid and normal to the two first truncations 114. In other examples the shape of the lens 112 may differ from that of FIG. 24a, for example to define an oblate spheroid.

The LED chip 110 of the package 109 of FIG. 24a is in the same position on its supporting substrate as is the LED chip 110 of the arrangement of FIG. 23a (which cannot be seen in FIG. 24a) on its generally identical supporting substrate 118, and the lens 112a of FIG. 24a is mounted directly over a light emitting surface of the light emitting diode die. It will be appreciated that the light emitting diode die of the package 109 of FIG. 24a is proximate to the second truncation 116.

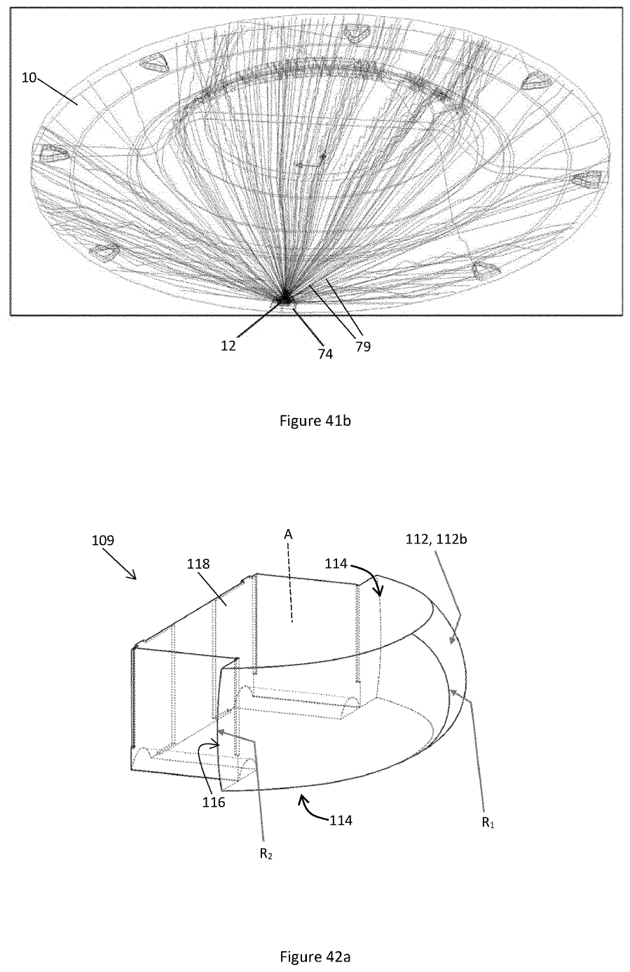

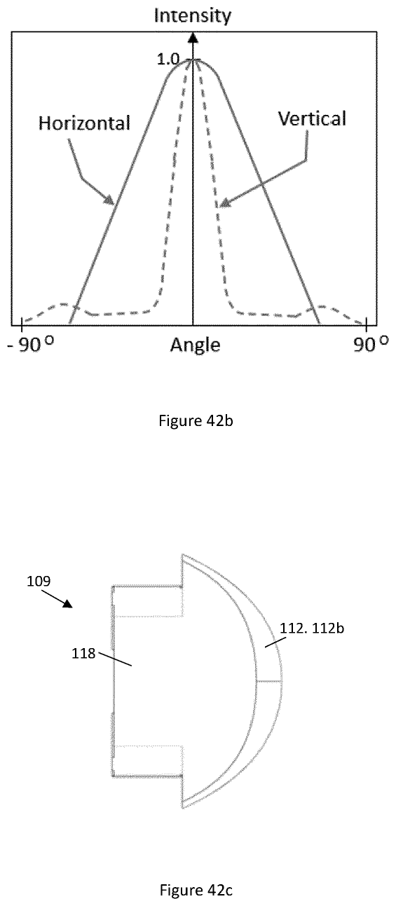

FIG. 42a shows another example of an HE-LED package 109. As in the example of FIG. 24a, the package 109 of FIG. 42a includes a light emitting diode die or chip (not shown) and a cylindrical lens 112. The LED chip of the package 109 of FIG. 42a is in the same position on its supporting substrate 118 as is the LED chip 110 of the arrangement of FIG. 23a on its supporting substrate 118. In the example of FIG. 42a, however, the cylindrical lens 112 takes the form of a truncated aspheric lens 112b. In particular, the cylindrical lens 112b is formed as an aspherical lens in a modified ellipsoidal body, the modified ellipsoidal body having two first truncations 114 and one second truncation 116. The two first truncations 114 are normal to the axis, A, of the modified ellipsoid and equidistant from a longest semidiameter of the modified ellipsoid. The first two truncations 114 are parallel to two axes of the oblate ellipsoid and to each other. The second truncation 116 is parallel to the other axis, A, of the oblate ellipsoid and normal to the two first truncations 114. The lens geometry in FIG. 42a is created by sweeping a vertical, variable radius along a horizontal, spline path. As will be appreciated from FIG. 42a, the lens 112b is more curved at the centre (i.e. at the first, short radius of curvature, R₁) and less at and towards the sides (i.e. at the second, long radius of curvature, R₂). In this example, because the lens surface at the sides is further away than the centre, less power is needed to generally collimate the diverging light on average.

FIGS. 24b and 42b illustrate the intensity distribution of light from the packages 109 of FIGS. 24a and 42a, respectively, in both the horizontal (x-z) and vertical (x-y) planes. It will be appreciated from FIGS. 24b and 42b that the package 109 of FIG. 42a utilising an aspherical lens 112b provides a narrower horizontal light distribution than the package 109 of FIG. 24a utilising an oblate ellipsoidal lens 112a. It will thus be appreciated that choice of lens 112 may affect the angular distribution of light from the package 109.

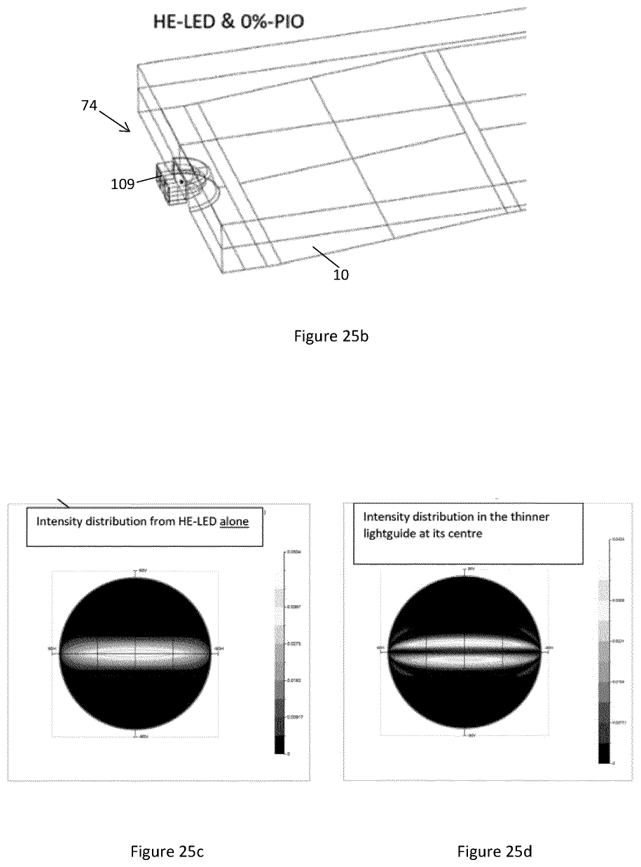

FIGS. 25a and 25b illustrate the HE-LED package 109 of FIG. 24a in combination with a pocket injection optic 74 geometry similar to that of FIG. 18a. FIG. 25c illustrates that the HE-LED lens 112 captures a full band of light from the LED die, around a 180 deg. arc from the die in the horizontal plane, which improves the optical coupling efficiency. FIG. 25d illustrates the intensity distribution of light from the light source 12 within the lightguide 10, in the active area of the lightguide 10 located in the thinner region 48 of the lightguide 10. This more efficient capture of the available light from the LED die results in less stray-light to suppress and manage in the system.

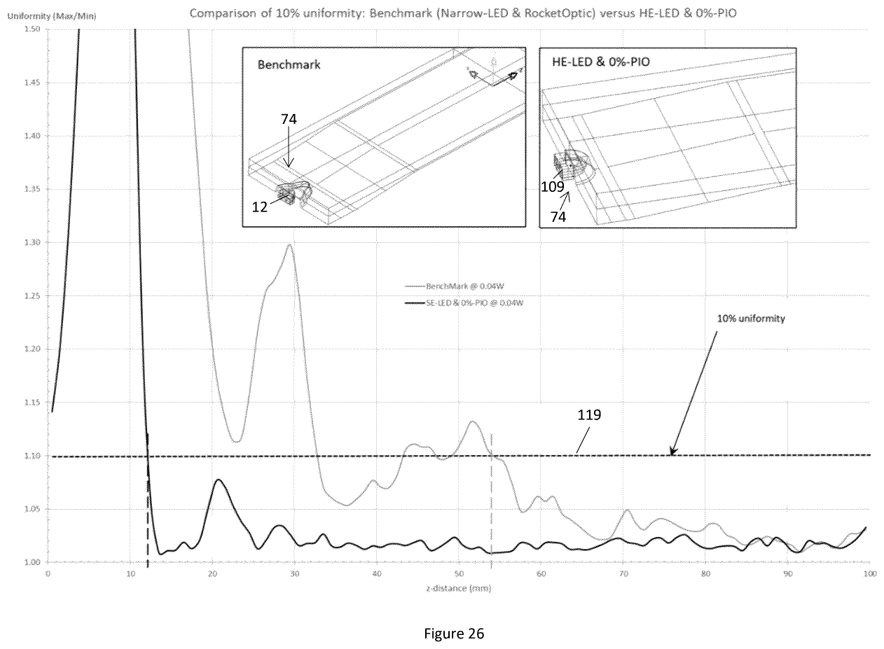

FIG. 26 illustrates that the ‘soft edges’ and smoother HE-LED intensity distribution significantly reduces the distance from the pocket injection optic 74 in the forward, or z, direction at which a uniformity target of 10% is achieved (represented by line 119 in FIG. 26), when compared to an arrangement such as that of FIG. 7. In other words, the use of the HE-LED package 109 allows for a more uniform light intensity distribution to be achieved closer to the pocket injection optic 74 in the lightguide 10. In the arrangement of FIG. 7, that does not utilise a HE-LED package 109, the intensity distribution is discontinuous, and requires a greater length of lightguide 10 to be traversed before the same light intensity uniformity is achieved.

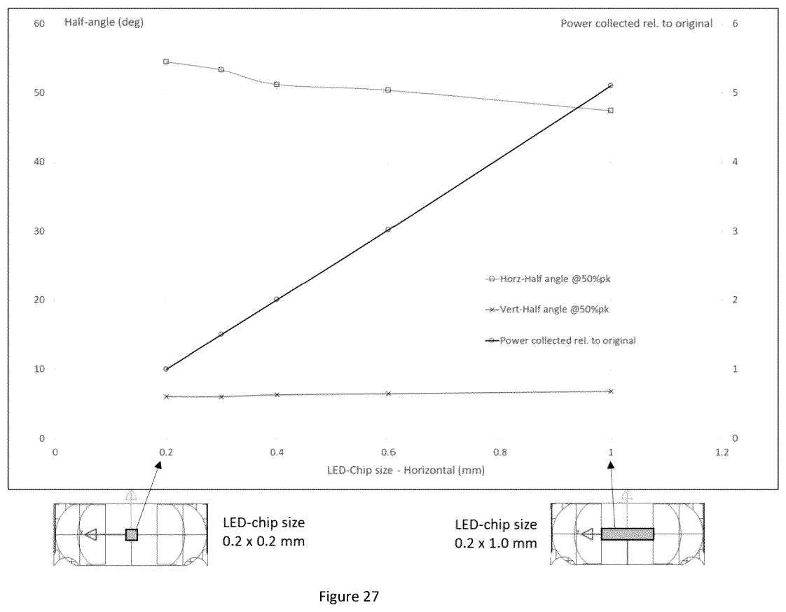

FIG. 27 shows how the HE-LED optical power is scalable by increasing the LED die size along the horizontal axis, without adversely affecting the HE-LED 109 angular distribution characteristics.

It has already been shown how light can be delivered into a lightguide 10, for example the top plate 10 of an arrangement such as that of FIG. 1. Next, management of light in the lightguide 10 is discussed. In particular, it is discussed how light can be proficiently managed in the lightguide 10, in order to control where the light can or cannot go.

One approach for management of light in the lightguide 10 is to use a distributed pattern of light-injection ‘points’ to create lighting zones where the touch-screen is active, i.e. active zones.

Another approach is to use light absorbing features (e.g. paint, over-mould, in-mould label (IML)) to either restrict the angular-range of ray-angles or to isolate optical geometric elements and control those areas that are inactive, i.e. to provide optically in-active zones.

Considering the first approach, an ‘active zone’ may be created by the placement of one or more pocket injection optics 74 in a pattern around a given lightguide geometry. In different embodiments, pocket injection optics 74 can be combined in different patterns or array configurations (e.g. square, rectangular, circular, and many other variants) to efficiently & uniformly distribute light across the active zone. For example, and with reference to FIG. 16, a first active zone 120 can be created using a circular array of wide-angle pocket injection optics 74a to illuminate a D-pad (i.e. directional pad) geometry. Nearby on the same lightguide 10 a second active zone 122 can be created using a pair of narrow-angled pocket injection optics 74b provided at either end of a touch region that defines a single slider geometry.

Key factors used to optimise the patterned light distribution in active-zones are:
The inherent pocket injection optic intensity distribution (which may be fixed);
The pattern used to place the pocket injection optics 74;
The spacing of the pocket injection optics 74 in the pattern; and
The orientation of the pocket injection optics 74.

The same optical targets (as discussed previously) apply to active zones; namely to:
Maximise the optical-power efficiency delivered into the active region;
Optimise the optical uniformity as close to a target percentage range as possible;
Minimise the distance from the pocket injection optic 74 to the edge of the touch-sensitive area (i.e. to the area at which the target uniformity is achieved);
Use the least number of pocket injection optics 74 possible to leave more room for other components in the assembly and to minimise electrical power consumption.

Examples of active-zone creation using multiple pocket injection optic 74 layout-geometries will now be discussed.

FIG. 28 illustrates a circular 3D ‘dial’ lightguide geometry utilising multiple pocket injection optics 74 (only one of which is labelled in FIG. 28 for clarity) to couple light into the lightguide 10. The dial lightguide 10 of FIG. 28, which may form a top plate of a dual plate arrangement similar to that of FIG. 1, is contoured, having a curved profile.

The lightguide 10 of FIG. 28 has an upper wall 124, a side wall 126 and a lower wall 128. The upper wall 124 defines a central region of the lightguide 10 that is substantially planar and generally circular in plan view. The side wall 126 extends downwardly and radially outwardly from a circumferential edge 130 of the upper wall 124 to the lower wall 128.

Light is injected into the lightguide 10 from a plurality of light sources 12 (only one of which is shown in FIG. 28) disposed in a plurality of light source cavities 30 (only one of which is labelled in FIG. 28 for clarity). Each light source 12 is located at a circumferential edge portion 132 of the lightguide 10, and undergoes total internal reflection in the lightguide 10.

In this example, the lightguide 10 includes sixteen light source cavities 30, each of which receives and houses a single light source 12. It will be appreciated that more or fewer light sources 12 and associated light source cavities 30 are possible in other examples.

Each light source cavity 30 of this example makes use of the pocket injection optic 74 geometry shown in FIG. 7. As in the arrangement of FIG. 7, each light source cavity 30 is defined by a recess in the underside of the lightguide 10, and is provided in a thicker section 46 of the lightguide 10. A tapered section 50 of the lightguide 10 joins the thicker section 46 of the lightguide 10 comprising the light source cavities 30 with a thinner section 48 of the lightguide 10. In this way, the side wall 126 and upper wall 124 of the lightguide 10 define the thinner section 48 of the lightguide 10, and the lower wall 128 defines the thicker and tapered sections 46, 50 of the lightguide 10.

The light sources 12 and associated light source cavities 30 are spaced at equal intervals around the circumferential edge portion 132 of the lightguide 10. Each light source 12 is arranged to face inwardly towards a central axis, C, of the lightguide 10, such that each light source 12 emits light towards the central axis, C.

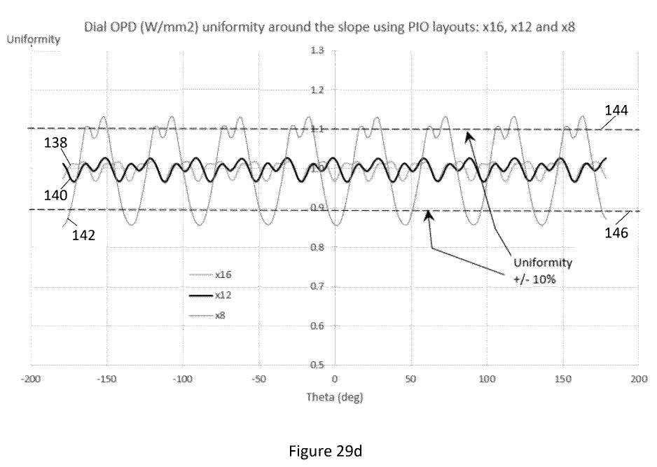

The arrangement of FIG. 28 provides the lightguide 10 with a touch detection region 134, i.e. an active zone or region, in which a touch on the lightguide 10 can be detected when the lightguide 10 is incorporated in an appropriate touch detection arrangement, such as a dual plate arrangement similar to that of FIG. 1. The touch detection region 134 in the example of FIG. 28 is defined by the side wall 126 and upper wall 124 of the lightguide 10 in this embodiment, but in other embodiments the active region 134 may also encompass at least a portion of the lower wall 128 of the lightguide 10. Either way, the light sources 12 of the lightguide 10 are disposed around a perimeter 136 of the active area or zone 134, the perimeter 136 defining a circle in plan view in this example. In other examples the shape of the perimeter 136 may vary, and may define an ellipse, rectangle or square in plan view, to name but a few non-limiting examples. The light sources 12 are spaced to form a substantially uniform light distribution in the active area 134 of the top plate 10. FIGS. 29a-d illustrate uniformity of light within dial lightguides 10 having a similar arrangement to that of FIG. 28. In particular, FIG. 29a shows the lightguide 10 of FIG. 28, comprising sixteen light sources 12 (not visible in FIG. 29a), FIG. 29b shows a lightguide 10 similar to that of FIG. 28 but comprising twelve equally spaced light sources 12 instead of sixteen, and FIG. 29c shows a lightguide 10 similar to that of FIG. 28 but comprising eight equally spaced light sources 12 instead of sixteen. In FIGS. 29a-c, lighter and darker portions of the lightguide 10 indicate irradiance within the lightguide 10, with lighter portions representing higher irradiance and darker portions representing lower irradiance. As will be appreciated from FIG. 29a-c, light irradiance within the lightguide 10 is generally not uniform within the lower wall 128 of the lightguide 10, which includes alternating light and dark portions (associated with the spacing between the light sources 12).

FIG. 29d illustrates the uniformity of the optical power density in the side wall 126 of each of the lightguides 10 of FIGS. 29a-c, at different angular positions about the central axis, C, of the lightguide 10. In FIG. 29d, curve 138 represents the lightguide arrangement of FIG. 29a, curve 140 represents the lightguide arrangement of FIG. 29b and curve 142 represents the lightguide arrangement of FIG. 29c. Lines 144 and 146 represent upper and lower limits within which the optical power density falls within a range of plus or minus 10%. With this in mind, it will be appreciated from FIG. 29d that the arrangements of FIGS. 29a and 29b provide an optical power density uniformity of +/−10% within the side wall 126, whereas the arrangement of FIG. 29c, using fewer light sources 12 for illumination, does not fall within this uniformity range at all positions across the side wall 126.

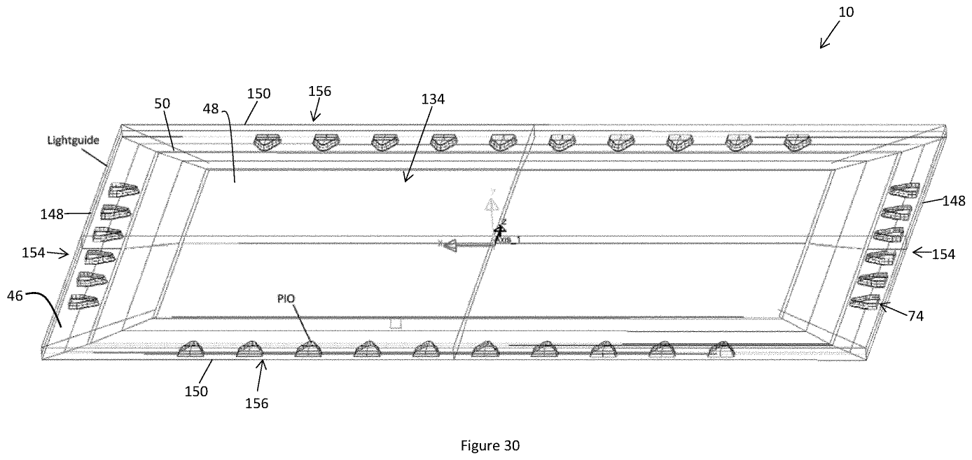

Turning now to FIG. 30, another example of active-zone creation using multiple pocket injection optics 74 (only one of which is labelled in FIG. 30), this time in a rectangular, flat lightguide plate 10. As with the lightguide 10 of FIG. 28, the lightguide of FIG. 30 may be incorporated in a dual plate arrangement utilising the underlying technology of FIG. 1.

The lightguide 10 of FIG. 30 is a substantially flat, planar plate having a rectangular shape in plan view, defined by two short side edges 148 joined by two long side edges 150. The short side edges 148 of the lightguide 10 have a length of 150 mm in this example, and the long side edges 150 of the lightguide 10 have a length of 210 mm in this example, but it will be understood that these dimensions may vary in other examples.

The lightguide 10 of FIG. 30 comprises a plurality of pocket injection optics 74 as shown in FIG. 7. The light source cavities 30 of the pocket injection optics 74 are located along edge portions 154, 156 of the lightguide 10. In the example of FIG. 30, the lightguide 10 includes six light source cavities 30 along each short side edge portion 154 of the lightguide 10, and ten light source cavities 30 along each long side edge portion 156 of the lightguide 10. Thus, in this example the lightguide 10 includes thirty two light source cavities 30, and thirty two associated light sources 12 disposed in the light source cavities 30 in use (i.e. thirty two pocket injection optics 74). It will be appreciated that the lightguide 10 may comprise more or fewer pocket injection optics 74 in other examples.

As in the arrangement of FIG. 7, each pocket injection optic 74 is provided in a thicker section 46 of the lightguide 10. A tapered section 50 of the lightguide 10 joins the thicker section 46 of the lightguide 10 to a thinner section 48 of the lightguide 10. In this example, the thinner section 48 of the lightguide 10 defines a central region of the lightguide 10 having a rectangular shape in plan view. The thinner section 48 defines an active region or zone 134 of the lightguide 10, in which a touch on the lightguide 10 can be detected when the lightguide 10 is incorporated in an appropriate touch detection arrangement, such as a dual plate arrangement similar to that of FIG. 1.

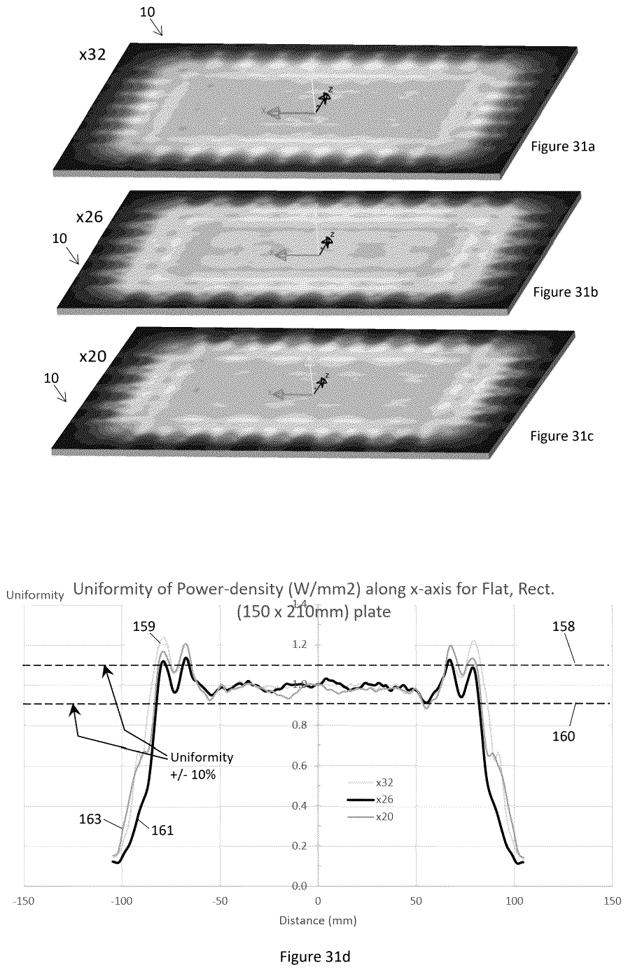

FIGS. 31a-d illustrate uniformity of light within rectangular lightguides 10 having a similar arrangement to that of FIG. 30. In particular, FIG. 31a shows the lightguide 10 of FIG. 30, comprising thirty two pocket injection optics 74 (not visible in FIG. 31a), FIG. 31b shows a lightguide 10 similar to that of FIG. 30 but comprising twenty six pocket injection optics 74, and FIG. 31c shows a lightguide 10 similar to that of FIG. 30 but comprising twenty pocket injection optics 74. Similarly to FIGS. 29a-c, lighter and darker portions of the lightguides 10 of FIG. 31a-c indicate the intensity distribution of light within the lightguide 10, with lighter portions representing higher intensity and darker portions representing lower intensity.

FIG. 31d illustrates the uniformity of the optical power density across a central axis, in particular the x-axis as illustrated in FIG. 30, in each of the lightguides of FIGS. 31a-c. Lines 158 and 160 represent upper and lower limits within which the optical power density falls within a range of plus or minus 10%. In FIG. 31d, curve 159 represents the lightguide arrangement of FIG. 31a, curve 161 represents the lightguide arrangement of FIG. 31b and curve 163 represents the lightguide arrangement of FIG. 31c. With this in mind, it will be appreciated from FIG. 31d that the arrangements of FIGS. 31a-c each provide an optical power density uniformity of +/−10% within a central region of the lightguide 10.

The concept of optically in-active zones will now be described in more detail. Optically in-active zones may be created through use of light absorbing elements, layers or coatings 58 that can be applied to the lightguide 10. Light absorbing layers or elements 58 may be used to isolate an individual optical geometry in one zone of the lightguide 10. Light absorbing layers or elements 58 my additionally or alternatively be used to prevent light from one zone of the lightguide 10 interfering with light from another zone of the lightguide 10, so as to avoid unwanted light leakage from the lightguide 10. In general, layers or coatings 58 provided on one or more regions of the first surface 23 of the lightguide 10, the second surface 25 of the lightguide 10, or both, may be used to inhibit internal reflection at that region of the relevant surface 23, 25, to provide optical separation between one part of the top plate 10 and another part of the top plate 10.

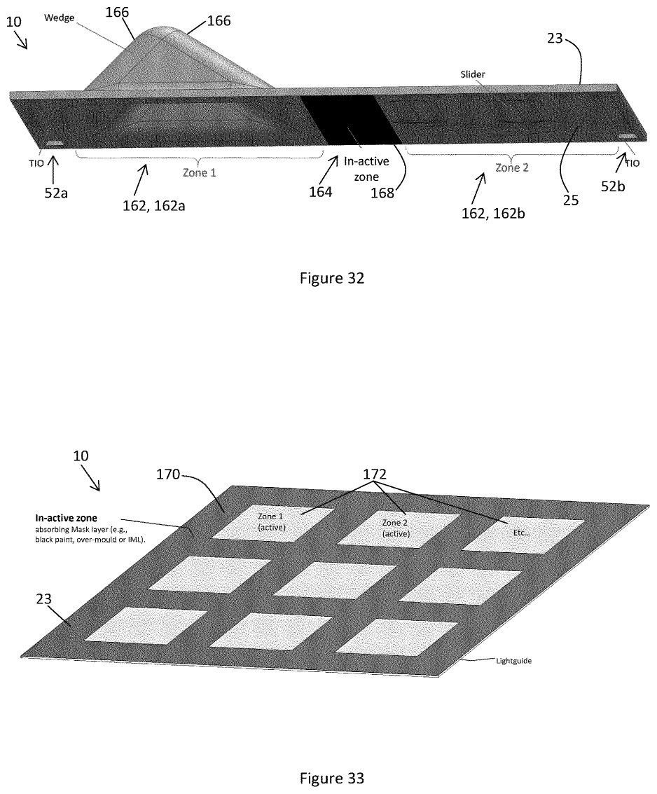

Referring to FIG. 32, a lightguide 10 having two optically active zones 162 separated by an optically inactive zone 164 is shown. The lightguide 10 of FIG. 32 uses a first trench injection optic 52a to couple light into the first active zone 162a and a second trench injection optic 52b to couple light into the second active zone 162b. The first active zone 162a defines a wedge geometry, having upwardly and downwardly sloping portions 166. The second active zone 162b defines a slider geometry. It should be appreciated that in other examples a lightguide 10 may incorporate more or fewer active zones 162, and the active zones 162 may define other geometries, such as dials etc. Furthermore, light injection geometries may be used to illuminate the active regions 162 of the lightguide 10, for example other trench injection optic 52 geometries or pocket injection optic 74 geometries. Further still, light sources 12 having different properties may be used to illuminate different active areas 162 of the lightguide 10.

Light is injected into the first active zone 162a with a narrow vertical angular range to minimise losses. However, after passage through the wedge geometry of the first active zone 162a, the angular range of the injected light from the first trench injection optic 52a may be broadened. In a lightguide 10 such as that shown in FIG. 32 without the inactive zone 164, if after passing through the first active zone 162a the light from the first trench injection optic 52a is allowed to continue into the second active zone 162b, and to pass through the slider geometry in the second active zone 162b, the angular range of the injected light may be broadened further such that some light rays may fall below the critical-angle limit at the upper or lower surface 23, 25 of the lightguide 10 (i.e. fall outside of the range of angles that undergo total internal reflection at one of these surfaces 23, 25) and be lost from the lightguide 10. Adding a light absorbing strip 168 to the underside of the lightguide 10 as shown in FIG. 32, between the first and second active zones 162a, 162b, creates an in-active zone 164 that isolates the first active zone 162a from the second active zone 162b.

Turning now to FIG. 33, another example of a lightguide 10 uses a single, absorbing in-active zone 170 to isolate multiple active zones 172. An absorbing mask layer 174 having multiple openings is provided on an upper surface 23 of a lightguide 10 to define multiple active regions 172 of the lightguide 10. Specifically, the active zones 172 of the lightguide 10, in which touch detection is possible, are defined in the openings 176 of the absorbing mask layer 174.

The mask layer 174 may comprise black paint, for example, or any other suitable opaque paint or material. In some examples the mask layer 174 may be formed through over-moulding or use of IML. As previously indicated, the mask layer 174 may be opaque to “working” light but transparent to other light, such as visible light if the device is configured to operate in the infrared.

In-active zones may use a variety of light absorption methods to control or prevent these optical losses, i.e. loss of injected light from the lightguide 10. Table 1 below summarises the pros and cons of three known light absorption methods (i.e. use of paint, two-shot-moulding or IML).

TABLE 1
Different methods of absorption for Zone-isolation

| | Implementation | | | |
|---|---|---|---|---|
| Method | time | Accuracy | Volume | Application |
| Paint | Short | Low | Low/medium | Prototypes |
| Two-shot | Long | Medium | High | Mass-production |
| IML/IMD | Long | High | High | Mass-production |

Examples of use of zone isolation will now be described.

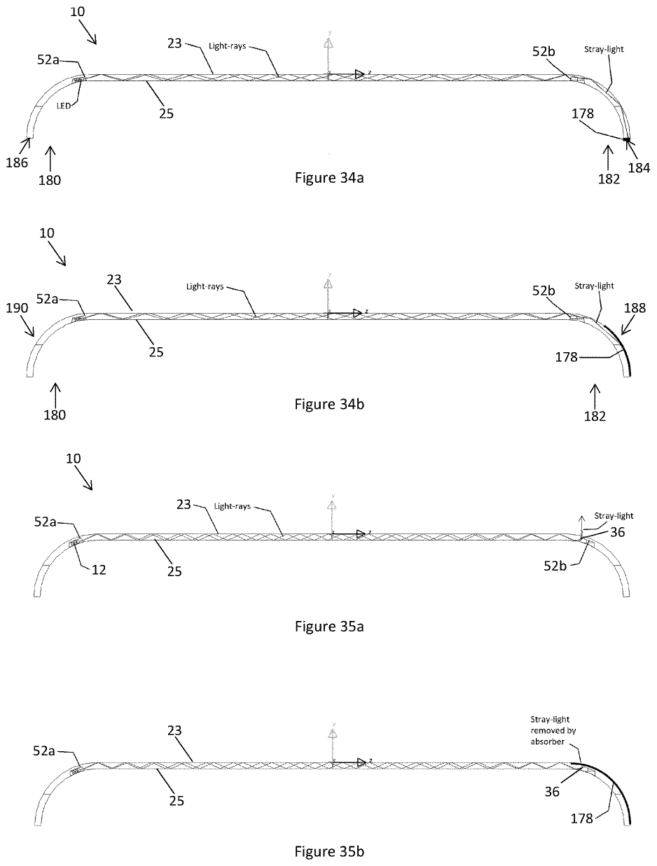

FIGS. 34a and 34b show examples of end-zone isolation in a symmetrical lightguide 10, in which an absorbing coating 178 is provided at some or all of a periphery of the top plate 10. A first trench injection optic 52a is positioned towards or near a first end 180 of the lightguide 10 and a second trench injection optic 52b is positioned at a second, opposing, end 182 of the lightguide 10.

In the arrangement of FIG. 34a, an absorber is provided on an end face of the lightguide 10 to prevent light from escaping the lightguide 10 through the end face. In this example, an absorber 178 is provided on a second end face 184 at the second end 182 of the lightguide 10, and light injected into the lightguide 10 from the first injection optic 52a at the first end 180 of the lightguide 10 is absorbed and blocked from exiting the lightguide 10 through the second end face 184. In some examples an absorber 178 may be provided on a first end face 186 at the first end 180 of the lightguide 10 to prevent light escaping from the lightguide 10 through the first end face 186, in particular light from the second trench injection optic 52b.

In the arrangement of FIG. 34b, an absorber 178 is provided along a portion of an end wall of the lightguide 10 to prevent light from escaping the lightguide 10 through the end wall. In this example, an absorber 178 is provided on the upper surface 23 of the lightguide 10, along a second end wall portion 188 at the second end 182 of the lightguide 10, such that light injected into the lightguide 10 from the first injection optic 52a is absorbed and blocked from exiting the lightguide 10 through the second end wall portion 188, and from continued travel in the lightguide 10. In some examples an absorber 178 may be provided on a first end wall portion 190 at the first end 180 of the lightguide 10 to prevent light escaping from the lightguide 10 through the first end wall portion 190, in particular light from the second trench injection optic 52b, and to prevent continued travel of that light in the lightguide 10. Although the absorber 178 is provided on the upper surface 23 of the lightguide 10 in the arrangement of FIG. 34b, it should be noted that in some examples an absorber 178 may be provided additionally or alternatively on the lower surface 25 of the lightguide 10.

In some examples absorbers 178 may be provided on end faces and end wall portions as necessary.

In this way, light traversing from one end of the lightguide 10 to the other is absorbed at the end face(s) and/or end wall(s) to prevent this light from escaping the lightguide 10 as stray light.

As shown in FIG. 35a, light from a first trench injection optic 52a may traverse the lightguide 10 and reflect upwards off the input-wall (i.e. the light coupling wall 36) of the second trench injection optic 52b through total internal reflection. Such light reflected at the second trench injection optic light coupling wall 36 may escape the lightguide 10 as stray light through the upper surface 23 of the lightguide 10. FIG. 35b illustrates a lightguide 10 in which an absorber 178 is provided on the upper surface 23 of the lightguide 10 to absorb and block escape of stray light reflected from the light coupling surface 36. For this, the absorber 178 extends above and across the second injection optic 52b and its light coupling wall 36. It should be noted that in some examples an absorber 178 may be provided additionally or alternatively to the lightguide lower surface 25 for this purpose. For example, an absorber 178 provided on the lower surface 25 of the lightguide 10, forward of the second trench injection optic 52b (i.e. away from the second end 182 of the lightguide 10 and towards the centre of the lightguide), may absorb light from the first injection optic 52a before this light can reach the second trench injection optic 52b. Similar is true for an absorber 178 that extends forwards of the second trench injection optic 52b on the upper surface 23 of the lightguide 10.

As has been indicated previously, the role of absorbers may be more complex, in that different properties may be desirable at different wavelengths. In some cases, the absorbers discussed above—for example, in separating active zones—may be absorbing at working wavelengths, but transmitting at others. This allows a device configured for detection in the infrared to use the “masking” area separating active zones in the visible—for example, a display disposed behind the touchscreen may be viewed through these separators.

In some examples absorbers may be used for aesthetic masking of sub-surface optics and components of the lightguide 10, to improve the aesthetics of an arrangement, or to simplify the appearance of the device to the user. In this regard, it is useful to add an opaque tint to the lightguide 10 that absorbs across visible wavelengths, but transmits across near infra-red (NIR) wavelengths used by the light source 12 (e.g. an LED light source 12)—the reverse arrangement to that discussed immediately above, in which there is opacity at a working wavelength but not in the visible. Such an opaque tint may be used, for example, to hide trench injection optics 52 or pocket injection optics 74, or any other components below the lightguide 10, from the view of a user, whilst allowing NIR light from the light source(s) 12 to propagate in the lightguide 10 unaffected, without being absorbed.

As mentioned already, the described lightguides 10 may be incorporated in a three-layer optical laminate such as that of FIG. 1 to provide a touch sensitive device 8, and the three-layer optical laminate may be positioned above a display to form a touch sensitive screen device 8.

In such an arrangement, the laminate upper and lower layers 10, 18 may be referred to as the transmission (Tx) and receiver (Rx) layers, respectively. The upper and lower layers 10, 18 are separated by an intermediate layer 14 which may comprise air or an optical material (referred to as the cladding) having a lower refractive-index than the upper and lower layers 10, 18. When the intermediate layer 14 comprises an optical material, the optical material defines an optically transmitting material layer.

The trench injection optic 52 and pocket injection optic 74 structures already discussed can be prototyped using a combination of standard machine-and-polish of acrylic or vacuum-casting techniques which are more suited to low-volume fabrication. However, the use of trench or pocket injection optics 52, 74 in the upper, transmission, layer 10 of such systems enables use of new construction methods that allow for medium to high volume manufacturing. For example, injection-moulding techniques can be used to create laminated structures to combine together some or all of the following optical elements and features: light injection, active & inactive-zones, light detection, decorative effects and display elements. This offers the following major advantages: minimal form-factor, lower component count, ease of assembly, improved transmission, aesthetics and ultimately lower overall fabrication & assembly costs. All of this can be designed to use surface-mounted electronic components, again to minimise form-factor and simplify assembly.

As discussed already, there are various schemes that can be employed in a lightguide 10 to absorb unwanted light, for example to prevent such light escaping through the roof 34 of a trench or pocket injection optic cavity 52, 74 (e.g. see FIG. 10 and FIG. 19), or to prevent light traversing from one active zone into another (e.g. see FIGS. 32 to 35). Such schemes using masking techniques allow for regions of a lightguide 10, and in particular of the first surface 23 of a lightguide 10, to be isolated from any other optical activity in the lightguide 10.

For example, paint having an appropriate absorption spectrum to match the light source(s) 12 may be used to block light hitting different surfaces and areas of the lightguide 10. However, the use of paint for this purpose involves a secondary process. The placement of the paint in this secondary process may not always be precisely controlled and the application of the paint is not cost effective for large volumes.

Two-shot moulding or in-mould labelling (IML)/in-mould decoration (IMD) processes allow for absorbing ink to be placed in the mould in a thin, secondary layer, and both provide an attractive alternative to the above. These fabrication techniques allow zones to be created on the touch surface (i.e. the upper surface of the top plate or lightguide) that can incorporate absorption masks to (a) hide components or features below the top-plate 10 from view, (b) to optically isolate one zone from another, or (c) to provide a decorative effect, as well as combinations of these effects (a) to (c). Once the moulding process is setup, this fabrication method provides a solution for large-scale manufacturing volumes of upper, or transmission, layers 10 with precise and effective stray light control.

IML has the distinct advantage (over two-shot moulding) in enabling attractive decorative effects that can make the surface look like many different materials (e.g. fabric, carbon-fibre, or leather). Typically, the LEDs 12 used for trench and pocket injection optics 52, 74 emit in the near infrared (NIR) region of the spectrum. The ink used in the IML can be selected to absorb light across the visible spectrum (i.e. 400-800 nm) and used to create decorative effects. The same inks are selected so that they do not absorb the NIR light from the LEDs 12 and do not interfere with the touch detection process.

Embodiments described in detail here generally describe use of acrylic (for example, poly (methyl methacrylate), or PMMA) sheets, but it should be noted that other types of 3-layer systems could be used—for example, glass layers may be used as an alternative to acrylic layers. The fabrication techniques discussed here are however particularly applicable to acrylic top and bottom layers.

Table 2 shows a comparison of the absorption-mask fabrication process using two-shot moulding, or IML/IMD:

TABLE 2
Comparison of absorption-mask fabrication process using Two-shot moulding or IML/IMD

| | | | Overall wall | |
|---|---|---|---|---|
| | | | section | |
| | | | thickness | Laminate layer |
| Method | Tooling & process | Absorption effects | range (mm) | characteristics |
| Two-shot moulding | Cheaper, easier to modify | Opacity, no patterns | Approx. 1.0-5.0 | Strong layer bond, |
| IML/IMD | Higher cost, more complex | Opacity, colour, | Approx. 1.0-3.0 | Medium layer bond strength, |
| | | decorative patterns | | Can cause warpage |

Regarding the overall wall section thickness ranges of Table 2, it should be noted that these values are those that are considered good practice for standard mass production.

Referring again to FIGS. 8a and 8b, replacing the intermediate air layer 14 in a 3-layer system including upper and lower layers of acrylic with a higher refractive-index material layer reduces the critical ray-angle at the boundary (i.e. the angle between the light ray and the surface boundary from approx. 48° to 26°). Thus, use of a higher refractive index intermediate layer instead of an intermediate air layer requires a more restricted angular range in the lightguide 10 in order for substantially all of the light to undergo total internal reflection at the boundary.

However, use of a cladding layer in a 3-layer laminate advantageously enables a reduction in the overall laminate thickness, compared to using a 1 mm air-gap. To provide this advantage, whilst also maintaining an angular range within which light undergoes total internal reflection at the boundaries between the upper and lower layers and the cladding that is as broad as possible, the material of the cladding is chosen to be a low refractive index material having a refractive index that is as close to that of air as possible. In some examples this cladding layer may take the form of an intermediate FEP layer, although other materials are possible.

Use of a low refractive index intermediate layer in place of an air gap provides for a reduction in the Fresnel reflections at the boundary between the upper (transmission) layer and the intermediate layer, and at the boundary between the lower (receiving) layer 18 and the intermediate layer 14. This improves the overall transmission and clarity of the laminate. Furthermore, use of a low refractive index intermediate layer in place of an air gap for the laminate construction improves the robustness of the fabricated assembly.

A disadvantage associated with replacing an air gap with a low refractive index intermediate layer 14 is to reduce evanescent-field strength due to the shallower average ray reflection angles. Furthermore, a laminate using a low refractive index intermediate layer 14 instead of air provides a lower optical coupling efficiency, due to the need to reduce the angular range for total internal reflection.

Fabrication scheme examples that show how the low refractive index intermediate layer can be combined with two-shot moulding or in-mould labelling will now be discussed.

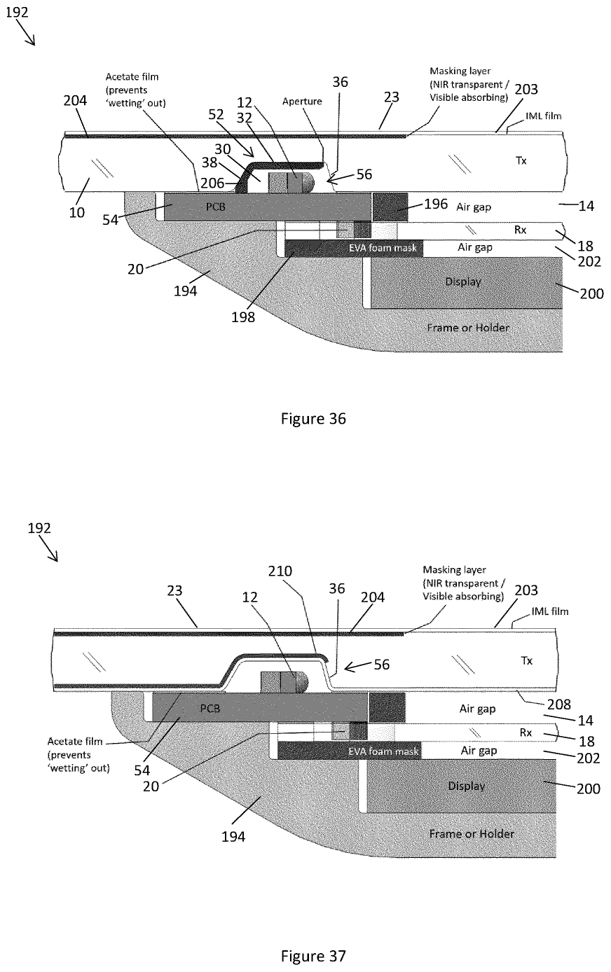

FIG. 36 shows a touch sensitive device formed from a composite 192. The composite 192 comprises an upper (transmission) layer 10 in the form of an optically transmissive sheet that defines a touch surface 23 of the device. The composite 192 further comprises a lower (receiving) layer 18 in the form of a further optically transmissive sheet, and an intermediate layer 14 between the upper and lower layers 10, 18 defined by an air gap. The upper layer 10 comprises a trench injection optic 52 comprising an array of light sources 12 disposed in the light source cavity 30 of the trench injection optic 52 (only one of which can be seen in FIG. 36). It should be appreciated that one or more pocket injection optics 74 could be incorporated in the arrangement of FIG. 36, in addition to or in place of the trench injection optic 52.

The light sources 12 in this example are LEDs operating in the near infrared (NIR) region of the spectrum. The device includes a single printed circuit board (PCB) 54 on which the light sources 12 are mounted, and the upper and lower layers 10, 18 are held on either side of the PCB 54 using a mechanical frame or holder 194. An ethylene-vinyl acetate (EVA) foam spacer 196 is inserted between the upper and lower layers 10, 18 to create or provide an air-gap 14 and hold them apart from one another. In this way, the lower layer or base plate 18 is mounted relative to the upper layer or top plate 10 such that if an external body touches a first surface 23 of the top plate 10, then light is coupled from a second surface 25 of the top plate 10 into the base plate 10 through a first or upper surface of the base plate 10. Another EVA spacer 198 is inserted between the lower layer 18 and a display 200 that also forms part of the composite 192, to create an air-gap 202 and hold the lower layer 18 and display 200 apart from one another.

Acetate-film is added to the upper or lower layer contact-points (i.e. areas of contact between the upper layer 10 and other components, and between the lower layer 18 and other components) to prevent the upper and lower layers 10, 18 from ‘wetting-out’ and causing the contained light to leak out. The upper layer 10 is injection-moulded with an IML insert in the tool to allow border, graphic, or texture effects to be added to part of the upper surface 23 of the upper layer 10, without completely covering the display 200 beneath. In addition, a thin layer of material 204 that is transparent to light in the near infrared region of the spectrum, but absorbs light in the visible region of the spectrum, is printed onto the underside of the IML film 203. As such, the LED 12 beneath the layer 204 is masked from the view of a user, whilst still allowing the NIR light emitted by the LED 12 to be totally internally reflected from the upper surface 23 of the upper layer 10. Similarly to the arrangement of FIG. 3, a separate opaque layer part 206, i.e. a light absorbing element, provided on the upper and rear surfaces 32, 38 of the light source cavity 30 between the light source 12 and the first surface of the lightguide 10 defines a light source aperture 56 in the arrangement of FIG. 36, that restricts the angular range of light emitted by the LED 12 that is coupled into the upper layer lightguide 10.

Alternative mask arrangements are possible. In one alternative mask arrangement (not shown), the opaque, near infrared absorbing coating 206 provided in the cavity 30 above the light source in the arrangement of FIG. 36 may be omitted, and a light source aperture 56 may instead be defined by the upper surface IML film arrangement. Specifically, a portion of the upper surface IML film arrangement above the cavity 30 may absorb in the near infrared region of the spectrum, in order to mimic the absorbing coating 206 of the arrangement of FIG. 36. In that case the upper surface IML film arrangement still retains the visible absorbing decorative effects as before in the arrangement of FIG. 36.

Sensors in the form of photodetectors 20 are positioned at edges of the lower layer 18 as required, for detection of light coupled from the upper layer 10 into the lower layer 18 in response to a touch on the upper surface 23 of the upper layer 10.

FIG. 37 shows another composite device 192 using a single PCB 54 (i.e. similar to FIG. 36). The device of FIG. 37 includes an additional IML film 208 that provides a similar function as does the layer that defines the light source aperture 56 in FIG. 36. Thus, the arrangement of FIG. 37 does not include the opaque layer part 206 provided on the roof and rear surfaces 32, 38 of the light source cavity 30, as the additional IML film 208 replaces this element. In particular, the additional IML film 208 has an opaque layer 210 which is used to restrict the angular range of light coupled into the upper layer 10 from the LED 12. This provides a single, laminated upper layer optical component for improved ease of assembly.

Similarly to the discussion in relation to FIG. 36, it would also be possible here to use an alternative mask arrangement (not shown). For example, one possible alternative mask arrangement may omit the additional IML film 208, and use a different upper surface IML film arrangement configured to absorb in the near infrared region in an appropriate region above the light source 12 to define a light source aperture 56. In that case the upper surface IML film arrangement could still retain the visible absorbing decorative effects as before in the arrangement of FIG. 36.

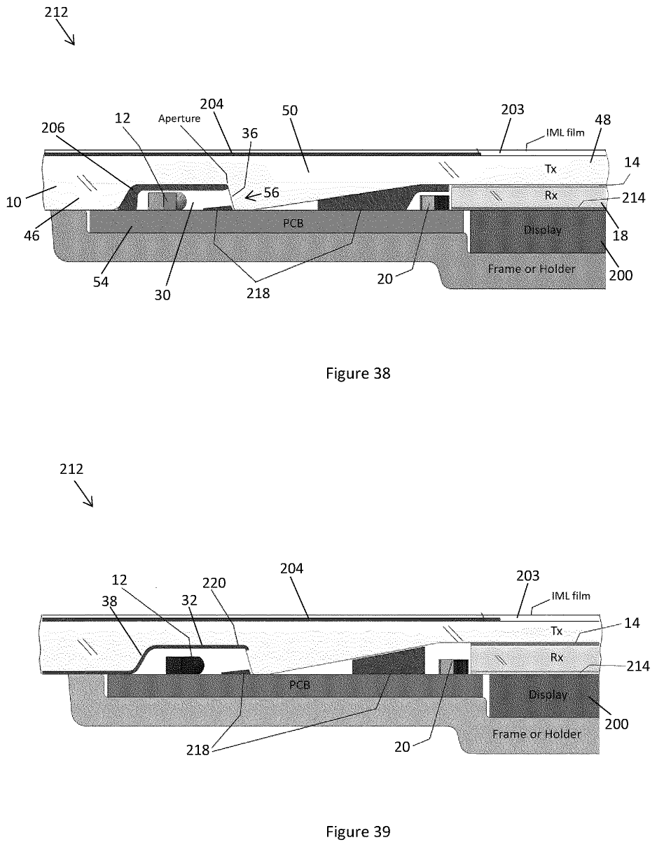

FIG. 38 shows a touch sensitive device formed by a laminate 212. The laminate 212 comprises an upper layer 10 that defines an optically transmissive sheet, a lower layer 18 that defines a further optically transmissive sheet, and an intermediate optical layer 14 that takes the form of a low refractive index interlayer between the upper and lower layers 10, 18. In this example, the low refractive index interlayer 14 is a single low refractive index optical adhesive layer, that provides an optical bond between the optically transmissive sheets 10, 18. In other examples this interlayer may take a different suitable form. For example, in some examples the interlayer may be formed by a stack of sub-layers.

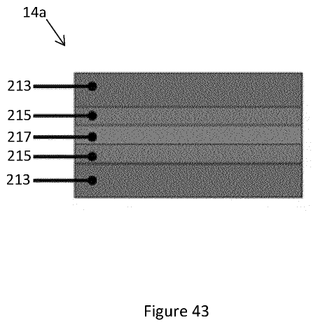

FIG. 43 shows an example of an interlayer 14a formed of a stack of sub-layers. The interlayer 14a includes upper and lower optically clear adhesive film layers 213 that engage and adhere to the upper and lower layer 10, 18, respectively. The interlayer 14a further includes two polycarbonate layers 215 and a central low refractive index adhesive layer 217. In the example of FIG. 43, the upper and lower adhesive layers 213 each have a thickness of 0.25 mm, the polycarbonate layers 215 each have a thickness of 0.1 mm and the central low refractive index adhesive layer 217 has a thickness of approximately 5 μm. In other examples, the material and form of the sub-layers may differ, and in particular the number and thicknesses of the sub-layers of the stack may vary.

Turning back to FIG. 38, the laminate 212 further comprises a display 200 positioned beneath the lower layer 18, and a further low refractive index layer 214 provided between the lower layer 18 and the display 200. As with the arrangements of FIGS. 36 and 37, the device of FIG. 38 includes a single PCB 54.

It will be appreciated that in contrast with the arrangements of FIGS. 36 and 37, the air layers between the upper and lower layers 10, 18, and the lower layer 18 and the display 200, have been replaced by the low refractive index layers 14, 214. The low refractive index layers 14, 214 are optically bonded to the upper and lower layers 10, 18 through optical bond layers. This requires an increased fabrication complexity, but, provides a single, laminated optical component for even simpler assembly.

As in the arrangement of FIG. 36, a separate opaque layer part 206 positioned at upper and rear positions within the light source cavity 30 defines the light source aperture 56 in the arrangement of FIG. 38, that restricts the angular range of light emitted by the LED 12 that is coupled into the upper layer lightguide 10. As discussed previously, in embodiments this opaque layer part 206 may be opaque only in the “working” near infrared range, and may in fact be transparent in some or all of the visible spectrum. Also as in the arrangement of FIG. 36, a thin layer of material 204 that is transparent to light in the near infrared region of the spectrum, but absorbs light in the visible region of the spectrum, is printed onto the underside of the IML film 203. The layer 204 is formed in the moulding process of the laminate. The device of FIG. 38 further includes absorbing structures 218 arranged to block light not desired to undergo total internal reflection and continue propagation in the lightguide 10.

It will be appreciated that the upper layer 10 of the arrangement of FIG. 38 has a tapered, wedge portion 50 between a thicker portion 46 of the lightguide 10 comprising the trench injection optic 52 and a thinner portion 48 of the lightguide 10 that defines an active area of the lightguide 10 in which a touch can be detected.

FIG. 39 shows another touch sensitive device formed using a laminate 212 (similar to that of FIG. 38). Many features of the device of FIG. 39 are the same as those of the arrangement of FIG. 38, and so will not be described again for conciseness. In contrast to the arrangement of FIG. 38, the arrangement of FIG. 39 includes an additional IML film 220 on the lower surface of the upper layer 10, positioned to extend across the rear and upper surfaces 38, 32 of the light source cavity 30, that provides a similar function as does the separate opaque layer part 206 that defines the light source aperture 56 in FIG. 38. The additional IML film 220 functions to control the angular range of light from the LED 12 that is coupled into the upper layer 10. It is noted that, as in the arrangement of FIG. 36, a thin layer of material 204 that is transparent to light in the near infrared region of the spectrum, but absorbs light in the visible region of the spectrum, is printed onto the underside of the IML film 203 in the arrangement of FIG. 39. The layer 204 is formed in the moulding process of the laminate.

It should be noted that alternative mask arrangements are possible, In one such alternative mask arrangement (not shown), the additional IML 220 above the LED 12 may be omitted, and a different upper surface IML film arrangement configured to absorb in the near infrared region in an appropriate region above the light source 12 to define a light source aperture 56 may be used. In that case the upper surface IML film arrangement could still retain the visible absorbing decorative effects, as before.

It will be appreciated from the above discussion that injection-moulding techniques can be used to combine the fabrication elements of light injection, light distribution and light isolation together, by combining them into a laminated structure. Light absorption layer(s) can be replaced with an in-mould-label (IML), and an air gap between upper and lower layers can be replaced by a low refractive index layer such as FEP.

It will be appreciated by a person skilled in the art that the invention could be modified to take many alternative forms to that described herein, without departing from the scope of the appended claims.

1. A packaged light emitting diode, comprising:
a light emitting diode die; and
a cylindrical lens mounted directly over a light emitting surface of the light emitting diode die, whereby light emitted through the cylindrical lens has a narrow angular distribution along a first axis and a broad angular distribution along a second axis orthogonal to the first axis.

2. The packaged light emitting diode of claim 1, wherein:
the cylindrical lens is formed as a truncated substantially oblate ellipsoidal lens in a body having two first truncations and one second truncation, wherein the two first truncations are normal to the axis of the oblate ellipsoid and equidistant from a longest semidiameter of the oblate ellipsoid, and are parallel to two axes of the oblate ellipsoid and to each other, and wherein the second truncation is parallel to the other axis of the oblate ellipsoid and normal to the two first truncations; and
wherein the light emitting diode die is proximate to the second truncation.

3. The packaged light emitting diode of claim 2, wherein the lens is an oblate spheroid.

4. The packaged light emitting diode of claim 1, wherein the cylindrical lens is formed as an aspherical lens in a modified ellipsoidal body, the modified ellipsoidal body having two first truncations and one second truncation, wherein the two first truncations are normal to the axis of the modified ellipsoid and equidistant from a longest semidiameter of the modified ellipsoid, and are parallel to two axes of the modified ellipsoid and to each other, and wherein the second truncation is parallel to the other axis of the modified ellipsoid and normal to the two first truncations; and
wherein the light emitting diode die is proximate to the second truncation, and wherein the ellipsoid is modified to have greater curvature than an ellipsoid in a direction normal to the light emitting surface of the light emitting diode die and to have lesser curvature than an ellipsoid in a direction parallel to the light emitting surface of the light emitting diode die.

5. The packaged light emitting diode of claim 2, wherein a length of the two first truncations normal to the light emitting surface of the light emitting diode die is more than half a length of the lens body normal to the light emitting surface of the light emitting diode die.

6. The packaged light emitting diode of claim 1, wherein the light emitting diode is a near infrared light emitting diode.

7. A touch sensitive apparatus, comprising:
a top plate having one or more light sources associated therewith, such that light from the one or more light sources is transmitted within the top plate with total internal reflection; and
a base plate having one or more detectors associated therewith for detecting light transmitted within the base plate,
wherein the top plate and the base plate are configured such that if an external body touches a first surface of the top plate, then light is coupled from a second surface of the top plate into the base plate through a first surface of the base plate;
wherein each of the one or more light sources is disposed within the top plate such that light from a light source is coupled into the body of the top plate through an input face of the top plate; and
wherein each of the one or more light sources is a packaged light emitting diode comprising:
a light emitting diode die; and
a cylindrical lens mounted directly over a light emitting surface of the light emitting diode die, whereby light emitted through the cylindrical lens has a narrow angular distribution along a first axis and a broad angular distribution along a second axis orthogonal to the first axis.

8. The touch sensitive apparatus of claim 7, wherein each light source is disposed within a recess, and wherein the input face is a face of the recess.

9. The touch sensitive apparatus of claim 7, wherein the mounting of each of the one or more light sources with respect to the input face is such that a combination of the lens of the light source and shaping of the input face is adapted to spread light substantially evenly in a plane of the top plate.

10. The touch sensitive apparatus of claim 7, wherein in the combination of the light source and the input face, the input face has no optical power.

11. The touch sensitive apparatus of claim 7, wherein in the combination of the light source and the input face, the input face has a lensing effect.

12. The touch sensitive apparatus of claim 7, wherein a wall of a refracting input face forms an angle to a plane of the top plate such that the refracting input face and the second surface of the top plate form an obtuse angle within the top plate.

13. The touch sensitive apparatus of claim 7, wherein each of the light sources is mounted at an angle to a plane of the top plate such that light emitted from the or each light source is predominantly directed obliquely towards the first surface.

14. The touch sensitive apparatus of claim 12, wherein each of the light sources is mounted such that light emitted from the light source is directed obliquely towards the refracting input face.

15. The packaged light emitting diode of claim 4, wherein a length of the two first truncations normal to the light emitting surface of the light emitting diode die is more than half a length of the modified ellipsoidal body normal to the light emitting surface of the light emitting diode die.

16. The touch sensitive apparatus of claim 7, wherein:
the cylindrical lens is formed as a truncated substantially oblate ellipsoidal lens in a body having two first truncations and one second truncation, wherein the two first truncations are normal to the axis of the oblate ellipsoid and equidistant from a longest semidiameter of the oblate ellipsoid, and are parallel to two axes of the oblate ellipsoid and to each other, and wherein the second truncation is parallel to the other axis of the oblate ellipsoid and normal to the two first truncations; and
wherein the light emitting diode die is proximate to the second truncation.

17. The touch sensitive apparatus of claim 7, wherein:
the cylindrical lens is formed as an aspherical lens in a modified ellipsoidal body, the modified ellipsoidal body having two first truncations and one second truncation, wherein the two first truncations are normal to the axis of the modified ellipsoid and equidistant from a longest semidiameter of the modified ellipsoid, and are parallel to two axes of the modified ellipsoid and to each other, and wherein the second truncation is parallel to the other axis of the modified ellipsoid and normal to the two first truncations; and
wherein the light emitting diode die is proximate to the second truncation, and wherein the ellipsoid is modified to have greater curvature than an ellipsoid in a direction normal to the light emitting surface of the light emitting diode die and to have lesser curvature than an ellipsoid in a direction parallel to the light emitting surface of the light emitting diode die.

18. The touch sensitive apparatus of claim 7, wherein the light emitting diode is a near infrared light emitting diode.
